(19) United States
(12) Patent Application Publication
(10) Pub. No.: US 2026/0182151 A1
(43) Pub. Date: Jun. 25, 2026

(54) DISPLAY SUBSTRATE AND DISPLAY APPARATUS

(71) Applicants: CHENGDU BOE OPTOELECTRONICS TECHNOLOGY CO. , LTD., Sichuan (CN); BOE TECHNOLOGY GROUP CO. , LTD., Beijng (CN)

(72) Inventors: Zilin ZHOU, Beijng (CN); Dian ZHANG, Beijng (CN); Yinglong HUANG, Beijng (CN); Haitao XIE, Beijng (CN); Di ZHANG, Beijng (CN); Xing WU, Beijng (CN); Yagui GAO, Beijng (CN)

(73) Assignees: CHENGDU BOE OPTOELECTRONICS TECHNOLOGY CO., LTD., Sichuan (CN); BOE TECHNOLOGY GROUP CO., LTD., Beijng (CN)

(21) Appl. No.: 18/727,434

(22) PCT Filed: May 12, 2023
(86) PCT No.: PCT/CN2023/093960

§ 371 Date: Jul. 9, 2024

(51) Int. Cl. H10K 59/122; H10K 59/12; H10K 59/80; H10K 102/00

(52) U.S. Cl. CPC H10K 59/122; H10K 59/1201; H10K 59/8723; H10K 2102/351

(57) ABSTRACT

A display substrate and a display apparatus are provided. The display substrate includes sub-pixels and a pixel defining pattern. Each sub-pixel includes a light-emitting functional layer having film layers; the pixel defining pattern includes openings and a defining portion surrounding the openings, the defining portion includes a first defining portion located between adjacent light-emitting elements; a size, in a second direction, of a cross section of the first defining portion is a cross-sectional size firstly increases and then decreases, a position with a maximum cross-sectional size is located at an isolation portion of the first defining portion; at least one layer in the light-emitting functional layer is located on a side of the first defining portion away from the base substrate, and an orthographic projection of an edge of the light-emitting functional layer falls into an orthographic projection of the first defining portion on the base substrate.

### TECHNICAL FIELD

At least one embodiment of the present disclosure relates to a display substrate and a display apparatus.

### BACKGROUND

With development of display technology, users have increasingly high requirements for performance of display apparatuses. In some products, by isolating material layers used for emitting light between adjacent sub-pixels to reduce signal crosstalk, performance requirements of high brightness and low power consumption of display apparatuses may be met as much as possible, so as to optimize display performance.

### SUMMARY

Embodiments of the present disclosure provide a display substrate and a display apparatus.

An embodiment of the present disclosure provides a display substrate, which includes: a base substrate, a plurality of sub-pixels, and a pixel defining pattern. The plurality of sub-pixels is located on the base substrate, each sub-pixel among at least some sub-pixels includes a light-emitting element including a light-emitting functional layer having a plurality of film layers, the plurality of film layers are stacked in a first direction; the pixel defining pattern includes a plurality of openings and a defining portion surrounding the plurality of openings, at least a portion of the light-emitting element are located in the opening. The defining portion includes a first defining portion located between adjacent light-emitting elements, a size, in a second direction, of a cross section of the first defining portion as sectioned by a plane is a cross-sectional size; in the first direction, the cross-sectional size firstly increases and then decreases, a position with a maximum cross-sectional size is located at an isolation portion of the first defining portion; both the plane and the second direction are perpendicular to an extension direction of the first defining portion, the first direction is perpendicular to the base substrate, and the second direction is perpendicular to the first direction, at least a portion of a pattern of at least one layer in the light-emitting functional layer is located on a side of the first defining portion that is away from the base substrate, and an orthographic projection of an edge of the at least portion of the pattern falls into an orthographic projection of the first defining portion on the base substrate.

For example, according to a display substrate of the present disclosure, the light-emitting element further includes a first electrode and a second electrode located on both sides of the light-emitting functional layer in the first direction, the first electrode is located between the light-emitting functional layer and the base substrate; the first defining portion includes a first sub-defining portion and a second sub-defining portion stacked, the first sub-defining portion is located between the second sub-defining portion and the base substrate, a material of the first sub-defining portion is different from a material of the second sub-defining portion, and the isolation portion includes a border between the first sub-defining portion and the second sub-defining portion.

For example, according to a display substrate of the present disclosure, an interface between the first sub-defining portion and the second sub-defining portion in contact with each other is the position with the maximum cross-sectional size.

For example, according to a display substrate of the present disclosure, a surface of the first sub-defining portion that is in contact with the second sub-defining portion is a first surface, a surface of the second sub-defining portion that is in contact with the first sub-defining portion is a second surface, and an orthographic projection of the second surface on the base substrate is completely located within an orthographic projection of the first surface on the base substrate.

For example, according to a display substrate of the present disclosure, a surface of the second sub-defining portion away from the base substrate includes a curved surface bent towards a side away from the base substrate or a flat surface parallel to the base substrate.

For example, according to a display substrate of the present disclosure, in at least some light-emitting elements, the second electrode includes one portion extending along the second direction, and the other portion having a component extending in the first direction.

For example, according to a display substrate of the present disclosure, the at least the portion of the pattern of the at least one layer in the light-emitting functional layer includes a first portion and a second portion, an orthographic projection of an edge of the first portion on the base substrate falls into an orthographic projection of the first defining portion on the base substrate, the edge of the first portion is located on a side of the isolation portion away from the base substrate, and an edge of the second portion is located on a side of the isolation portion close to the base substrate.

For example, according to a display substrate of the present disclosure, in the first direction, a distance between the edge of the first portion and the edge of the second portion is 0.2 μm to 0.5 μm.

For example, according to a display substrate of the present disclosure, second electrodes of at least some of adjacent sub-pixels are continuously arranged at an edge of the isolation portion.

For example, according to a display substrate of the present disclosure, the cross section includes a side edge located between the position with the maximum cross-sectional size and the base substrate, an included angle between at least a portion of the side edge and the second direction is 95° to 105°, and a maximum size of the first sub-defining portion in the first direction is 0.7 μm to 1 μm; the cross section includes an edge line located on a side of the position with the maximum cross-sectional size away from the base substrate, an included angle between a tangent line at a point connecting the edge line and the position with the maximum cross-sectional size and the second direction is 35° to 45°, and a maximum size of the second sub-defining portion in the first direction is 1.15 μm to 1.25 μm.

For example, according to a display substrate of the present disclosure, a maximum size of the first defining portion in the second direction is 13 μm to 19 μm.

For example, according to a display substrate of the present disclosure, two adjacent sub-pixels arranged along the second direction are configured to emit light of different colors, and one first defining portion is provided between the two adjacent sub-pixels.

For example, according to a display substrate of the present disclosure, second electrodes of adjacent sub-pixels are isolated at an edge of the isolation portion.

For example, according to a display substrate of the present disclosure, the cross section includes a side edge located between the position with the maximum cross-sectional size and the base substrate, an included angle between at least a portion of the side edge and the second direction is 100° to 110°, and a maximum size of the first sub-defining portion in the first direction is 1 μm to 1.2 μm, the cross section includes an edge line located on a side of the position with the maximum cross-sectional size away from the base substrate, an included angle between a tangent line at a point connecting the edge line and the position with the maximum cross-sectional size and the second direction is 35° to 45°, and a maximum size of the second sub-defining portion in the first direction is 0.9 μm to 1.1 μm.

For example, according to a display substrate of the present disclosure, a maximum size of the first defining portion in the second direction is 5 μm to 9 μm.

For example, according to a display substrate of the present disclosure, the defining portion further includes a second defining portion, the second defining portion is closely adjacent to an edge of the light-emitting region of the light-emitting element, and an extension direction of the second defining portion is the same as the extension direction of the first defining portion; in the first direction, a size of the second defining portion is smaller than a size of the first defining portion, and a material of the second defining portion is the same as that of the second sub-defining portion.

For example, according to a display substrate of the present disclosure, in the first direction, the size of the second defining portion is larger than a size of the second sub-defining portion.

For example, according to a display substrate of the present disclosure, two adjacent sub-pixels arranged along the second direction are configured to emit light of different colors, two first defining portions are provided at an interval between the two adjacent sub-pixels, or, one first defining portion and one second defining portion are provided at an interval between the two adjacent sub-pixels.

For example, according to a display substrate of the present disclosure, the position with the maximum cross-sectional size is further away from the base substrate than a surface of the light-emitting functional layer away from the base substrate.

For example, according to a display substrate of the present disclosure, the material of the first sub-defining portion has a first photosensitive characteristic such that the first sub-defining portion is polymerized under illumination; and the material of the second sub-defining portion has a second photosensitive characteristic such that the second sub-defining portion is decomposed under illumination.

For example, according to a display substrate of the present disclosure, the material of the first sub-defining portion includes phenolic resin and propylene glycol monomethyl ether acetate, and/or the material of the second sub-defining portion includes polyimide resin and propylene glycol monomethyl ether acetate.

For example, according to a display substrate of the present disclosure, the first defining portion is located between light-emitting regions of light-emitting elements of two adjacent sub-pixels, and an orthographic projection of the first defining portion on the base substrate respectively overlaps with orthographic projections of first electrodes of the light-emitting elements of the two adjacent sub-pixels on the base substrate.

For example, according to a display substrate of the present disclosure, an orthographic projection of the first defining portion surrounding the opening on the base substrate has a shape of closed ring.

For example, according to a display substrate of the present disclosure, an orthographic projection of the first defining portion surrounding the opening on the base substrate has a shape of non-closed ring, and second electrodes of adjacent light-emitting elements are at least partially connected at a notch of the non-closed ring.

For example, according to a display substrate of the present disclosure, edges of light-emitting regions of at least some sub-pixels include a first edge closely adjacent to the first defining portion and a second edge closely adjacent to the second defining portion, first edges of light-emitting regions of two adjacent sub-pixels are arranged at least partially opposite to each other, and orthographic projections of first defining portions respectively closely adjacent to the first edges of light-emitting regions of the two adjacent sub-pixels on the base substrate have a first interval therebetween; the second edge of a light-emitting region of a certain sub-pixel is arranged at least partially opposite to the first edge of a light-emitting region of a sub-pixel adjacent to the certain sub-pixel, and orthographic projections of defining portions respectively closely adjacent to the second edge and the first edge opposite to each other on the base substrate have a second interval.

For example, according to a display substrate of the present disclosure, in an arrangement direction of the sub-pixels, a size of the first interval is larger than a size of the second interval.

For example, according to a display substrate of the present disclosure, the plurality of sub-pixels includes a plurality of first color sub-pixels, a plurality of second color sub-pixels, and a plurality of third color sub-pixels, the plurality of sub-pixels is arranged as a plurality of first sub-pixel groups and a plurality of second sub-pixel groups arranged alternately along a first arrangement direction; the first sub-pixel group includes first color sub-pixels and second color sub-pixels arranged alternately along a second arrangement direction, the second sub-pixel group includes third color sub-pixels arranged along the second arrangement direction, and the first arrangement direction intersects with the second arrangement direction; the first sub-pixel group and the second sub-pixel group are shifted from each other in the second arrangement direction, respective first color sub-pixels among the at least some first color sub-pixels are each surrounded by eight sub-pixels, and the eight sub-pixels include third color sub-pixels and second color sub-pixels alternately arranged.

For example, according to a display substrate of the present disclosure, the plurality of sub-pixels includes a plurality of first color sub-pixels, a plurality of second color sub-pixels, and a plurality of third color sub-pixels, the plurality of sub-pixels includes a plurality of pixel units arranged in an array along a first arrangement direction and a second arrangement direction, each pixel unit includes one first color sub-pixel, one second color sub-pixel, and one third color sub-pixel; in each pixel unit, the second color sub-pixel and the third color sub-pixel are arranged alternately along the first arrangement direction, the first color sub-pixel and the third color sub-pixel are arranged alternately along the second arrangement direction, and the first arrangement direction intersects with the second arrangement direction.

For example, according to a display substrate of the present disclosure, one first defining portion is provided between adjacent sub-pixels.

For example, according to a display substrate of the present disclosure, an orthographic projection of a portion of the light-emitting functional layer of the light-emitting element that is located in the opening on the base substrate at least partially overlaps with an orthographic projection of the first sub-defining portion surrounding the opening on the base substrate.

At least one embodiment of the present disclosure further provides a display substrate which includes a base substrate, a plurality of sub-pixels, a pixel defining pattern, and an isolation structure. The plurality of sub-pixels is located on the base substrate, each sub-pixel among at least some sub-pixels including a light-emitting element, the light-emitting element includes a light-emitting functional layer as well as a first electrode and a second electrode located on both sides of the light-emitting functional layer along a first direction, the first electrode is located between the light-emitting functional layer and the base substrate, and the first direction is perpendicular to the base substrate; the pixel defining pattern includes a plurality of openings and defining portions surrounding the plurality of openings, and at least a portion of the light-emitting element is located within the opening; the isolation structure is located between defining portions respectively adjacent to two adjacent openings, and a material of the isolation structure being different from a material of the defining portion. In a second direction, a maximum size of a first edge line away from the base substrate of a cross section of the isolation structure, as sectioned by a plane, is larger than a maximum size of a second edge line close to the base substrate of the cross section, the plane and the second direction are both perpendicular to an extension direction of the defining portion, and the second direction is perpendicular to the first direction; between at least two adjacent light-emitting elements, at least one layer of the light-emitting functional layer is isolated at an edge of the isolation structure, and at least a portion of a second electrode corresponding to at least one certain light-emitting element extends from a light-emitting region of the certain light-emitting element to a light-emitting region of at least one of light-emitting elements adjacent to the certain light-emitting element.

For example, according to a display substrate of the present disclosure, a material of the isolation structure includes phenolic resin and propylene glycol monomethyl ether acetate, and/or a material of the defining portion includes polyimide resin and propylene glycol monomethyl ether acetate.

For example, according to a display substrate of the present disclosure, the cross section includes a side edge located between the position with the maximum cross-sectional size and the base substrate, an included angle between at least a portion of the side edge and the second direction is 95° to 105°, and a maximum size of the isolation structure in the first direction is 0.7 μm to 1 μm; a cross section of the defining portion that is sectioned by the plane includes a third edge line away from the base substrate, an included angle between a tangent line of at least a portion of the third edge line and the second direction is 35° to 45°, and a maximum size of the defining portion in the first direction is 1.15 μm to 1.25 μm.

For example, according to a display substrate of the present disclosure, a maximum size of the isolation structure in the second direction is 3 μm to 6 μm.

For example, according to a display substrate of the present disclosure, in the second direction, a distance between the isolation structure and a light-emitting region adjacent to the isolation structure is 4 μm to 7 μm.

At least one embodiment of the present disclosure further provides a display apparatus, which includes any display substrate as mentioned above.

### BRIEF DESCRIPTION OF DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a schematic diagram of a display substrate.

FIG. 2 is a cross-sectional view of a display substrate provided by at least one embodiment of the present disclosure.

FIG. 3 is a cross-sectional view of another display substrate provided by at least one embodiment of the present disclosure.

FIG. 4 is a cross-sectional view of still another display substrate provided by at least one embodiment of the present disclosure.

FIG. 5 is a cross-sectional view of still another display substrate provided by at least one embodiment of the present disclosure.

FIG. 6 is a partial schematic plan view of a display substrate provided by at least one embodiment of the present disclosure.

FIG. 7 is a partial schematic plan view of another display substrate provided by at least one embodiment of the present disclosure.

FIG. 8 is a cross-sectional view of another display substrate provided by at least one embodiment of the present disclosure.

FIG. 9 is a cross-sectional view of still another display substrate provided by at least one embodiment of the present disclosure.

FIG. 10 is a partial schematic plan view of a display substrate corresponding to FIG. 8 provided by at least one embodiment of the present disclosure.

FIG. 11 is a partial schematic plan view of still another display substrate corresponding to FIG. 8 provided by at least one embodiment of the present disclosure.

FIG. 12 is a partial schematic plan view of still another display substrate corresponding to FIG. 8 provided by at least one embodiment of the present disclosure.

FIG. 13 is a partial schematic plan view of still another display substrate corresponding to FIG. 8 provided by at least one embodiment of the present disclosure.

FIG. 14 is a partial schematic plan view of a display substrate corresponding to FIG. 9 provided by at least one embodiment of the present disclosure.

FIG. 15 is a partial schematic plan view of still another display substrate corresponding to FIG. 9 provided by at least one embodiment of the present disclosure.

FIG. 16 is a partial schematic plan view of still another display substrate corresponding to FIG. 9 provided by at least one embodiment of the present disclosure.

FIG. 17 is a partial schematic plan view of still another display substrate corresponding to FIG. 9 provided by at least one embodiment of the present disclosure.

FIG. 18 is a cross-sectional view of still another display substrate provided by at least one embodiment of the present disclosure.

FIG. 19 is a partial schematic plan view of a display substrate corresponding to FIG. 18 provided by at least one embodiment of the present disclosure.

FIG. 20 is a partial schematic plan view of still another display substrate corresponding to FIG. 18 provided by at least one embodiment of the present disclosure.

FIG. 21 is a schematic diagram of a display apparatus provided by an embodiment of the present disclosure.

FIG. 22 is a spectral schematic diagram of a display substrate provided by an embodiment of the present disclosure.

FIG. 23 to FIG. 40 are flow charts of a fabrication process of a display substrate provided by at least one embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects.

Features such as “parallel”, “perpendicular” and “identical”, etc. used in the embodiments of the present disclosure all include strictly defined features such as “parallel”, “perpendicular” and “identical”, as well as cases where certain errors are included such as “substantially parallel”, “substantially perpendicular” and “substantially identical”, considering that errors related to measurement and measurement of a specific quantity (e.g., limitations of a measurement system) indicate that such features are within an acceptable deviation range for a specific value determined by those ordinarily skilled in the art. For example, the expression “substantially” may indicate that features are within one or more standard deviations, or within 10% or 5% of a value. When a quantity of a component is not specifically specified in the following text of the embodiments of the present disclosure, it means that the quantity of such component may be one or more, or may be understood as at least one. The expression “at least one” refers to one or more, and “more” refers to at least two.

Usually, an organic light-emitting diode (OLED) emits light through carrier injection and recombination as driven by an electric field with an organic semiconductor material and a light-emitting material. For example, organic light-emitting diodes may be divided into a passive matrix driving OLED (PMOLED) and an active matrix driving OLED (AMOLED) according to a driving mode, and the active matrix driving OLED has advantages such as low fabrication costs, low power consumption, applicability to direct-current driving of a portable apparatus, and wide operation temperature range, etc.

FIG. 1 is a schematic diagram of a display substrate. As shown in FIG. 1, the display substrate 001 includes a planarization layer 010, a pixel defining layer 011, a first electrode 012, a light-emitting functional layer 020, and a second electrode 013. For example, the first electrode 012 may be an anode, and the second electrode 013 may be a cathode. For example, the light-emitting functional layer 020 may include a plurality of film layers, for example, a hole transport layer 021, a light-emitting layer 022, and an electron transport layer 023, etc. FIG. 1 schematically shows that the first electrode 012 is electrically connected with a corresponding pixel circuit through a connection hole NO located in the planarization layer 010, and the pixel circuit is located between the planarization layer 010 and the base substrate 10. FIG. 1 does not show a specific position of the pixel circuit.

FIG. 1 shows a light-emitting element EMI and a light-emitting element EM2 of adjacent sub-pixels; for example, the light-emitting element EMI is configured to emit red light, and the light-emitting element EM2 is configured to emit green light, that is, the light-emitting element EMI corresponds to a light-emitting layer 0221 emitting red light, and the light-emitting element EM2 corresponds to a light-emitting layer 0222 emitting green light. For example, a plurality of film layers of the light-emitting element EMI and a plurality of film layers the light-emitting element EM2 may be structures independent of each other, but it is not limited thereto. For example, in some embodiments, the light-emitting layer of the light-emitting element EMI and the light-emitting layer of the light-emitting element EM2 may also be an integrated structure and fabricated with an opening mask. It should be noted that in order to illustrate clearly, Fig. 1 only shows some film layers in the display substrate, for example, the display substrate further includes a plurality of other film layers, for example, an encapsulation layer, etc.

However, with continuous improvement of product resolution, a pixel defining layer gap between of sub-pixels in the display substrate is constantly reduced; when a film layer with strong conductivity (e.g., a charge generation layer) in light-emitting elements is set as a whole-surface film layer, crosstalk between adjacent sub-pixels easily occurs, for example, a green sub-pixel may drive an adjacent red sub-pixel to emit light in a low gray scale. Such a phenomenon is especially evident in a low-grayscale display state, ultimately leading to brightness degradation and color coordinate shift of sub-pixels in monochrome, and further affecting a display effect of the display substrate.

In some solutions, an isolation spacer arranged between adjacent sub-pixels may isolate at least one film layer in the light-emitting functional layer of adjacent sub-pixels, thereby reducing a probability of crosstalk between adjacent sub-pixels. The isolation spacer proposed in the above-described solution usually adopts a “sandwich” structure of SiO/SIN/SiO; gaps are prone to occur due to weak adhesion between SiO and a pixel defining layer, leading to a phenomenon of “SiO peeling” (e.g., a phenomenon of “SiO peeling from a pixel defining layer”); meanwhile, in a fabrication process of the “sandwich” structure, thickness accuracy of SiN is difficult to control, which may lead to uneven thickness of the entire “sandwich” structure, resulting in poor cutting capability of the isolation spacer, moreover, change of a thickness of SiN in the “sandwich” structure causes greater difficulties and great process fluctuations, resulting in poor capability for controlling an “undercut” structure formed by the “sandwich” structure; in addition, the “sandwich” structure is usually formed by using a dry etching process, which may cause damage to the anode in the light-emitting element during the fabrication process, and is prone to an anode “blast” phenomenon; for example, the anode “blast” phenomenon may have a risk of injury in explosion, etc.

The embodiments of the present disclosure provide a display substrate and a display apparatus.

A display substrate provided by at least one embodiment of the present disclosure includes: a base substrate, a plurality of sub-pixels, and a pixel defining pattern. The plurality of sub-pixels is located on the base substrate, each sub-pixel among at least some sub-pixels includes a light-emitting element, the light-emitting element includes a light-emitting functional layer having a plurality of film layers, the plurality of film layers are stacked in a first direction; the pixel defining pattern includes a plurality of openings and a defining portion surrounding the plurality of openings, at least a portion of the light-emitting element is located in the opening, the defining portion includes a first defining portion located between adjacent light-emitting elements; a size of a cross section of the first defining portion in a second direction, as sectioned by a plane, is a cross-sectional size, in the first direction, the cross-sectional size firstly increases and then decreases, a position with a maximum cross-sectional size is located at an isolation portion of the first defining portion; both the plane and the second direction are perpendicular to an extension direction of the first defining portion; the first direction is perpendicular to the base substrate, the second direction is perpendicular to the first direction; at least a portion of a pattern of at least one layer in the light-emitting functional layer is located on a side of the first defining portion that is away from the base substrate, and an orthographic projection of an edge of the at least portion of the pattern falls into an orthographic projection of the first defining portion on the base substrate.

In the display substrate provided by the embodiment of the present disclosure, the first defining portion having the isolation portion is arranged between adjacent light-emitting elements, and the cross-sectional size of the first defining portion in the first direction firstly increases and then decreases, which may effectively block at least one film layer in the light-emitting functional layer, so as to reduce a risk of crosstalk between adjacent sub-pixels and brightness decrease due to sub-pixel leakage; and the first defining portion has a simple structural form, which is easy to fabricate.

The display substrate and the display apparatus provided by the present disclosure are described below with reference to the accompanying drawings.

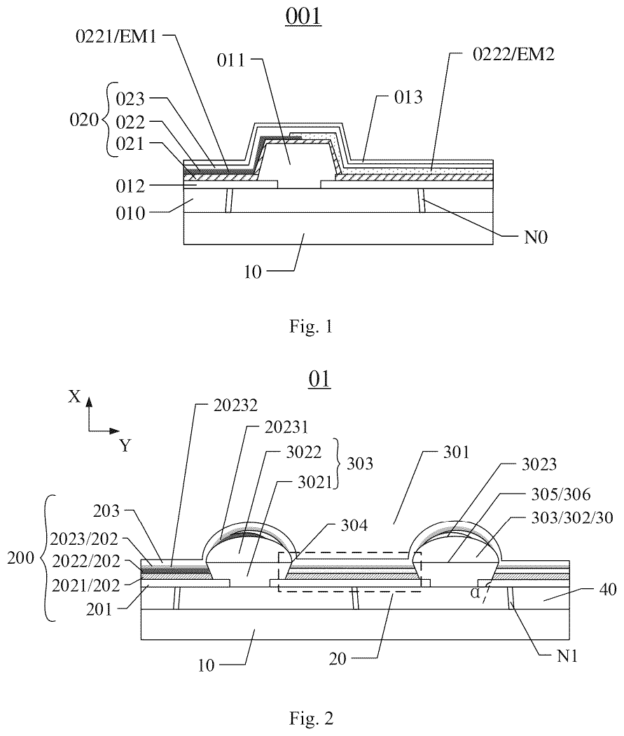

FIG. 2 is a cross-sectional view of a display substrate provided by at least one embodiment of the present disclosure.

As shown in FIG. 2, the display substrate 01 includes a base substrate 10 and a plurality of sub-pixels 20. The plurality of sub-pixels 20 is located on the base substrate 10, and each sub-pixel 20 among at least some sub-pixels 20 includes a light-emitting element 200. The light-emitting element 200 includes a light-emitting functional layer 202 having a plurality of film layers, and the plurality of film layers is stacked in a first direction X. For example, the light-emitting element 200 may further include a first electrode 201 and a second electrode 203 located on both sides of the light-emitting functional layer 202 in the first direction X, the first electrode 201 is located between the light-emitting functional layer 202 and the base substrate 10, and the first direction X is perpendicular to the base substrate 10.

For example, as shown in FIG. 2, the light-emitting functional layer 202 may include a plurality of film layers, for example, a hole transport layer 2021, a light-emitting layer 2022, and an electron transport layer 2023, the hole transport layer 2021 and the electron transport layer 2023 are respectively located on both sides of the light-emitting layer 2022. For example, the light-emitting functional layer 202 may further include a hole injection layer, an optical coupling layer, and an electron injection layer, etc. For example, the above-described film layers are all common film layers of the light-emitting element, and may be referred to as common layers. For example, the first electrode 201 may be an anode, and the second electrode 203 may be a cathode. For example, the anode may be made of a transparent conductive material having high work functions, for example, indium tin oxide (ITO), but it is not limited thereto. For example, the cathode may be made of a material having high conductivity and low work functions, for example, the cathode may be made of a metal material.

As shown in FIG. 2, the display substrate 01 further includes a pixel defining pattern 30, the pixel defining pattern 30 includes a plurality of openings 301 and a defining portion 302 surrounding the plurality of openings 301. At least a portion of the light-emitting element 200 is located in the opening 301. The opening 301 of the pixel defining pattern 30 is configured to define a light-emitting region of the light-emitting element 200. For example, the light-emitting element 200 may include a portion located in the opening 301, and a portion overlapping with the defining portion 302 in a direction perpendicular to the base substrate 10. For example, as shown in FIG. 2, the opening 301 of the pixel defining pattern 30 is configured to expose the first electrode 201 of the light-emitting element 200, and the exposed first electrode 201 is at least partially in contact with the light-emitting functional layer 202 in the light-emitting element 200.

FIG. 2 also schematically shows that a structural layer 40 is further provided on a side of the first electrode 201 of the light-emitting element 200 that is away from the second electrode 203; for example, the structural layer 40 may include film layers such as a planarization layer, a layer where an active semiconductor pattern is located, a film layer where a gate line is located, a film layer where a data line is located, a plurality of insulation layers, etc. FIG. 2 schematically shows that the first electrode 201 is electrically connected with a corresponding pixel circuit through a connection hole N1 located in the structural layer 40; at least a portion of the pixel circuit is located in the structural layer 40, and FIG. 2 does not show a specific position of the pixel circuit.

As shown in FIG. 2, the defining portion 302 includes a first defining portion 303 located between adjacent light-emitting elements 200, a size, in a second direction Y, of a cross section of the first defining portion 303 that is sectioned by a plane is a cross-sectional size; both the plane and the second direction Y are perpendicular to an extension direction of the first defining portion 303; and the second direction Y is perpendicular to the first direction X. In the first direction X, the cross-sectional size firstly increases and then decreases, and a position with a maximum cross-sectional size is located at an isolation portion 304 of the first defining portion 303. At least a portion of a pattern of at least one layer in the light-emitting functional layer 202 is located on a side of the first defining portion 303 that is away from the base substrate 10, and an orthographic projection of an edge of the at least portion of the pattern falls into an orthographic projection of the first defining portion 303 on the base substrate 10, that is, at least one layer of the light-emitting functional layer 202 is isolated at the edge of the isolation portion 304 that faces the light-emitting element 200. The above-described edge is formed by at least a portion of the pattern of at least one layer of the light-emitting functional layer 202 being isolated by the isolation portion 304, and the edge is different from an edge of the portion of the pattern in the at least one layer of the light-emitting functional layer 202 corresponding to a sub-pixel in the fabrication process.

For example, as shown in FIG. 2, the cross section of the first defining portion 303 that is sectioned by the above-described plane has portions located on both sides of the isolation portion 304, and the two portions have different shapes, or may also have the same or similar shapes, which will not be limited in the embodiments of the present disclosure. For example, the cross section of the first defining portion 303 that is sectioned by the above-described plane has a portion located on a side of the isolation portion 304 away from the base substrate 10, and the portion has a shape of “arc”; the cross section of the first defining portion 303 that is sectioned by the above-described plane has a portion located on a side of the isolation portion 304 close to the base substrate 10, the portion has a shape of “trapezoid”, and the “trapezoid” has a lower base further away from the base substrate 10 than an upper base, but it is not limited thereto.

For example, as shown in FIG. 2, in the first direction X, the cross-sectional size of the first defining portion 303 may firstly increase gradually and then decrease gradually, but it is not limited thereto. For example, the cross-sectional size of the first defining portion 303 may increase non-continuously or decrease non-continuously, as long as the isolation portion 304 is ensured to be located in the position with the maximum cross-sectional size, which will not be limited in the embodiments of the present disclosure.

For example, as shown in FIG. 2, a position in the cross section of the first defining portion 303 that corresponds to the isolation portion 304 has a sharp corner, such a structural feature may allow the first defining portion 303 to effectively disconnect at least one film layer in the light-emitting functional layer 202, which may reduce probability of crosstalk between two adjacent sub-pixels and brightness degradation in sub-pixel; and is favorable for reducing a risk of color mixing on the display substrate when adjacent sub-pixels emit light of different colors.

For example, as shown in FIG. 2, for at least one layer in the light-emitting functional layer 202, for example, the electron transport layer 2023, at least a portion of a pattern in the layer includes a first portion 20231 and a second portion 20232; an orthographic projection of an edge of the first portion 20231 on the base substrate 10 falls into an orthographic projection of the first defining portion 303 on the base substrate 10, the edge of the first portion 20231 is located on a side of the isolation portion 304 that is away from the base substrate 10, and an edge of the second portion 20232 is located on a side of the isolation portion 304 that is close to the base substrate 10. For example, the first portion 20231 and the second portion 20232 are respectively two portions of the electron transport layer 2023 that are formed through partitioning by the isolation portion 304; an orthographic projection of the first portion 20231 on the base substrate 10 and an orthographic projection of the second portion 20232 on the base substrate 10 may be continuous in the second direction Y, but it is not limited thereto.

For example, as shown in FIG. 2, in the first direction X, a distance between the edge of the first portion 20231 and the edge of the second portion 20232 may be 0.2 μm to 0.5 μm, for example, may be at least one of 0.2 μm to 0.4 μm, 0.3 μm to 0.5 μm, 0.2 μm to 0.3 μm, and 0.25 μm to 0.45 μm, but it is not limited thereto.

For example, as shown in FIG. 2, at least one layer of the above-described light-emitting functional layer 202 may be a layer isolated at the isolation portion 304, for example, may also be a hole transport layer 2021, a light-emitting layer 2022, etc., which will not be limited in the embodiments of the present disclosure.

For example, as shown in FIG. 2, the first defining portion 303 includes a first sub-defining portion 3021 and a second sub-defining portion 3022 stacked, the first sub-defining portion 3021 is located between the second sub-defining portion 3022 and the base substrate 10, and the isolation portion 304 includes a border between the first sub-defining portion 3021 and the second sub-defining portion 3022.

As shown in FIG. 2, a material of the first sub-defining portion 3021 is different from a material of the second sub-defining portion 3022. For example, as shown in FIG. 2, the material of the first sub-defining portion 3021 has a first photosensitive characteristic such that the first sub-defining portion 3021 is polymerized under illumination, and the material of the second sub-defining portion 3022 has a second photosensitive characteristic such that the second sub-defining portion 3022 is decomposed under illumination. The first sub-defining portion 3021 and the second sub-defining portion 3022 have different photosensitive characteristics, which facilitates process fabrication and reduces a risk of damage to the first sub-defining portion 3021 by the second sub-defining portion 3022 during, for example, an exposure process.

For example, as shown in FIG. 2, the material of the first sub-defining portion 3021 may include phenolic resin and propylene glycol monomethyl ether acetate, while the material of the second sub-defining portion 3022 may include polyimide resin and propylene glycol monomethyl ether acetate, but it is not limited thereto. For example, in some embodiments, the material of the second sub-defining portion 3022 may also include acrylic or polyethylene terephthalate, etc.

In this way, the first sub-defining portion 3021 is made of a material different from that of the second sub-defining portion 3022, so as to more easily adhere to the second sub-defining portion 3022 well, which may reduce a risk of peeling, misalignment, and other phenomena; meanwhile, the above-described materials allow shape and size of the first sub-defining portion 3021 to be more controllable, which facilitates to carry out more variations and is more favorable for adapting to different size requirements, with less process fluctuations; on the other hand, the first sub-defining portion 3021 and the second sub-defining portion 3022 may be formed without dry etching process, for example, may be formed by using a wet etching process, so that impact on the first electrode 201 in the light-emitting element 200 is relatively small.

For example, as shown in FIG. 2, an interface between the first sub-defining portion 3021 and the second sub-defining portion 3022 in contact with each other is the position with the maximum cross-sectional size. For example, a surface of the first sub-defining portion 3021 that is in contact with the second sub-defining portion 3022 is a first surface 305, a surface of the second sub-defining portion 3022 that is in contact with the first sub-defining portion 3021 is a second surface 306, and the interface between the first surface 305 and the second surface 306 in contact with each other corresponds to the position with the maximum cross-sectional size of the first defining portion 303. For example, the position with the maximum cross-sectional size of the first defining portion 303 has strong isolation capability, which may effectively isolate at least one film layer in the light-emitting functional layer 202.

For example, as shown in FIG. 2, the position with the maximum cross-sectional size of the first defining portion 303 is further away from the base substrate 10 than a surface on a side of the light-emitting functional layer 202 that is away from the base substrate 10, so that at least one film layer in the light-emitting functional layer 202 may be effectively isolated by the isolation portion 304 of the first defining portion 303.

For example, as shown in FIG. 2, the hole transport layer 2021 and the electron transport layer 2023 in the light-emitting functional layer 202 are both isolated by the isolation portion 304 of the first defining portion 303, but the embodiment of the present disclosure is not limited thereto. For example, one of the hole transport layer 2021 and the electron transport layer 2023 in the light-emitting functional layer 202 is isolated by the isolation portion 304 of the first defining portion 303, but it is not limited thereto.

For example, as shown in FIG. 2, an orthographic projection of the second surface 306 of the second sub-defining portion 3022 on the base substrate 10 is completely located within an orthographic projection of the first surface 305 of the first sub-defining portion 3021 on the base substrate 10, so that a size of the first surface 305 in the second direction Y is no less than a size of the second surface 306 in the second direction Y, allowing an edge of the first surface 305 in the second direction Y to protrude as much as possible from the first defining portion 303, such that the isolation portion 304 of the first defining portion 303 has good partition capability, but the embodiment of the present disclosure is not limited thereto.

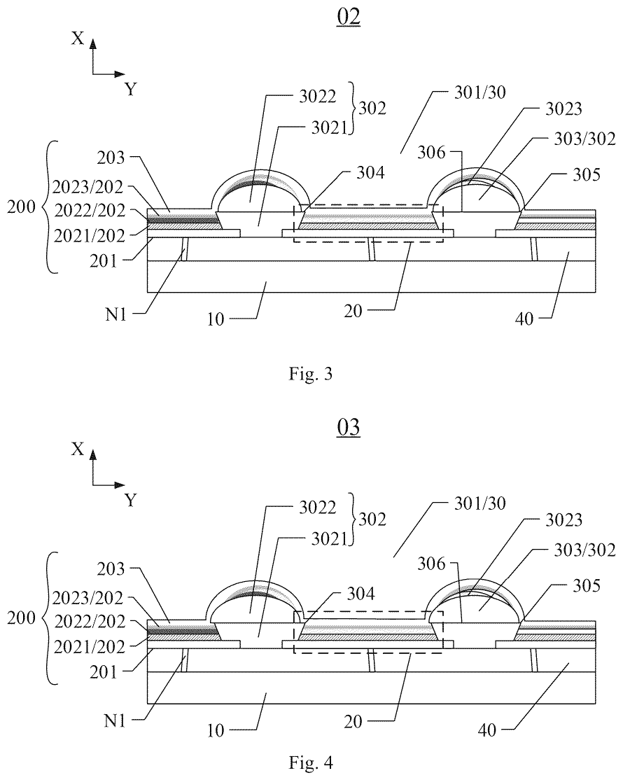

FIG. 3 is a cross-sectional view of another display substrate provided by at least one embodiment of the present disclosure, and FIG. 4 is a cross-sectional view of still another display substrate provided by at least one embodiment of the present disclosure.

For example, as shown in FIG. 3, the display substrate 02 differs from the display substrate 01 in the structure of the first defining portion; the remaining structures are the same or similar, and no details will be repeated here. In the display substrate 02, the size of the first surface 305 in the second direction Y is greater than the size of the second surface 306 in the second direction Y, and at least a portion of the first surface 305 that is close to the edge is exposed outside the second sub-defining portion 3022, so that both sides of the first sub-defining portion 3021 each have a sharp corner, to effectively isolate at least one film layer in the light-emitting functional layer 202.

For example, as shown in FIG. 4, the display substrate 03 differs from the display substrate 01 in the structure of the first defining portion; the remaining structures are the same or similar, and no details will be repeated here. In the display substrate 03, the first sub-defining portion 3021 and the second sub-defining portion 3022 are shifted from each other by a certain distance in the second direction Y, so that at least a portion of the first surface 305 of the first sub-defining portion 3021 that is close to the edge is exposed outside the second sub-defining portion 3022, and at least a portion of the second surface 306 of the second sub-defining portion 3022 that is close to the edge is exposed outside the first sub-defining portion 3021, so that the first sub-defining portion 3021 and the second sub-defining portion 3022 both have obvious sharp corners, which may effectively block at least one film layer in the light-emitting functional layer 202.

For example, in some embodiments of the present disclosure, at least one edge of the first defining portion 303 may have an obvious sharp corner, so that the light-emitting functional layer 202 between adjacent light-emitting elements 200 may be blocked, which will not be limited in the embodiments of the present disclosure.

For example, as shown in FIG. 2, the cross section of the first defining portion 303 includes a side edge located between the position with the maximum cross-sectional size and the base substrate 10, an included angle o between at least a portion of the side edge and the second direction Y is 95° to 105°, and a maximum size of the first sub-defining portion 3021 in the first direction X is 0.7 μm to 1 μm. For example, the cross section of the first defining portion 303 includes an edge line located on a side of the position with the maximum cross-sectional size that is away from the base substrate 10, an included angle between a tangent line at a point connecting the edge line and the position with the maximum cross-sectional size and the second direction Y is 35° to 45°; and the maximum size of the second sub-defining portion 3022 in the first direction X is 1.15 μm to 1.25 μm.

For example, as shown in FIG. 2, the cross section of the first sub-defining portion 3021 has a shape of inverted trapezoid, and an included angle between a side edge of the trapezoid and the second direction Y is 95° to 105°. The edge line of the cross section of the second sub-defining portion 3022 that is away from the base substrate 10 has an arc shape, and an end portion of the edge line is located in the isolation portion 304. For example, the tangent line at the point connecting the edge line and the position with the maximum cross-sectional size may be a tangent line of a line connecting the edge line and an edge of the interface between the first surface 305 and the second surface 306, but it is not limited thereto. For example, an included angle a between a side edge of the cross section of the first defining portion 303 that is located between the position with the maximum cross-sectional size and the base substrate 10 and the second direction Y may be at least one of 95° to 100°, 98° to 103°, 96° to 102°, and 97° to 104°, but it is not limited thereto. For example, the maximum size of the first sub-defining portion 3021 in the first direction X may be at least one of 0.7 μm to 0.9 μm, 0.8 μm to 0.9 μm, and 0.75 μm to 0.85 μm, but it is not limited thereto. For example, the included angle between the tangent line at the point connecting the edge line and the position with the maximum cross-sectional size and the second direction Y may be at least one of 35° to 40°, 37° to 43°, and 38° to 41°, the edge line of the cross section of the first defining portion 303 is on a side of the position with the maximum cross-sectional size away from the base substrate 10, but it is not limited thereto. For example, the maximum size of the second sub-defining portion 3022 in the first direction X may be at least one of 1.18 μm to 1.20 μm, 1.17 μm to 1.23 μm, 1.19 μm to 1.25 μm, and 1.20 μm to 1.24 μm, but it is not limited thereto.

For example, as shown in FIG. 2, the maximum size of the first defining portion 303 in the second direction Y may be 13 μm and 19 μm, for example, may be at least one of 14 μm to 19 μm, 13 μm to 18 μm, 14 μm to 18 μm, 15 μm to 17 μm, and 14 μm to 15 μm, but it is not limited thereto. For example, in some embodiments, a plurality of (e.g., 2 to 4) first defining portions 303 may be provided between light-emitting regions of two adjacent light-emitting elements 200, but it is not limited thereto, which may enhance an isolation effect on at least one film layer in the light-emitting functional layer 202.

Such arrangement may allow at least one film layer in the light-emitting functional layer in adjacent sub-pixels to be isolated at the isolation portion 304 of the first defining portion 303, which reduces a risk of crosstalk between adjacent sub-pixels 20, allows second electrodes 203 of at least some sub-pixels 20 arranged adjacent to each other to be continuously arranged at the edge of the isolation portion 304, and thus is favorable for improving display uniformity.

For example, as shown in FIG. 2, in at least some light-emitting elements 200, the second electrode 203 includes one portion extending along the second direction Y, and the other portion having a component extending in the first direction X. For example, the defining portion 302 is provided between light-emitting regions of two adjacent light-emitting elements 200, the second electrode 203 includes a portion located on a side of the first electrode 201 that is away from the base substrate 10 and a portion located on a side of the defining portion 302 that is away from the base substrate 10; because the two portions are arranged continuously, at least a portion of the second electrode 203 extends in the first direction X. For example, the second electrode 203 may be laid in a whole layer and has an integrated structure, but it is not limited thereto.

For example, as shown in FIG. 2, two adjacent sub-pixels 20 arranged along the second direction Y are configured to emit light of different colors, and one first defining portion 303 is provided between the two adjacent sub-pixels 20. For example, the first defining portion 303 is located between two light-emitting elements 200 of the two adjacent sub-pixels 20, thereby isolating at least one film layer in the light-emitting functional layer 202, which may reduce a risk of crosstalk and color mixing between sub-pixels 20 emitting light of different colors.

For example, as shown in FIG. 2, the first defining portion 303 is closely adjacent to light-emitting elements 200 located on both sides thereof, and the first defining portion 303 at least partially overlaps with the light-emitting element 200.

For example, as shown in FIG. 2, the first defining portion 303 is located between light-emitting regions of light-emitting elements 200 of two adjacent sub-pixels 20, and an orthographic projection of the first defining portion 303 on the base substrate 10 respectively overlaps with orthographic projections of first electrodes 201 of the light-emitting elements 200 of the two adjacent sub-pixels 20 on the base substrate 10. By such arrangement, a separation distance between adjacent sub-pixels 20 may be reduced, so that sub-pixels 20 in the display substrate 01 have a more compact arrangement, which is favorable for expanding an area of the light-emitting region of the light-emitting element 200 and improving luminous efficiency of the light-emitting element 200.

For example, as shown in FIG. 2, the hole transport layer 2021, the light-emitting layer 2022, and the electron transport layer 2023 in the light-emitting element 200 are all disconnected by the isolation portion 304. An orthographic projection of a portion of the light-emitting functional layer 202 of the light-emitting element 200 that is located in the opening 301 on the base substrate 10 at least partially overlaps with an orthographic projection of the first sub-defining portion 3021 surrounding the opening 301 on the base substrate 10. For example, when at least one film layer in the light-emitting functional layer 202 is isolated, a portion of the film layer is located in the opening 301, and an orthographic projection of an edge of the portion that is close to the first defining portion 303 on the base substrate 10 overlaps with the orthographic projection of the first defining portion 303 on the base substrate 10. For example, an edge portion of the portion of the film layer that is close to of the first defining portion 303 may be located on a side of a side face close to the base substrate 10, the side face is located between the isolation portion 304 of the first defining portion 303 and the base substrate.

Thus, the cross-sectional size of the first defining portion 303 in the second direction Y firstly increases and then decreases, and the position with the maximum cross-sectional size is located at the isolation portion 304 of the first defining portion 303, which is beneficial to dispose the edge portion of the isolated film layer in the light-emitting functional layer 202 outside an emission range of the light-emitting element 200, so as to reduce impact on luminous efficiency of the light-emitting element 200.

For example, as shown in FIG. 2, a surface 3023 of the second sub-defining portion 3022 away from the base substrate 10 includes a curved surface curved towards a side away from the base substrate 10, but the embodiment of the present disclosure is not limited thereto.

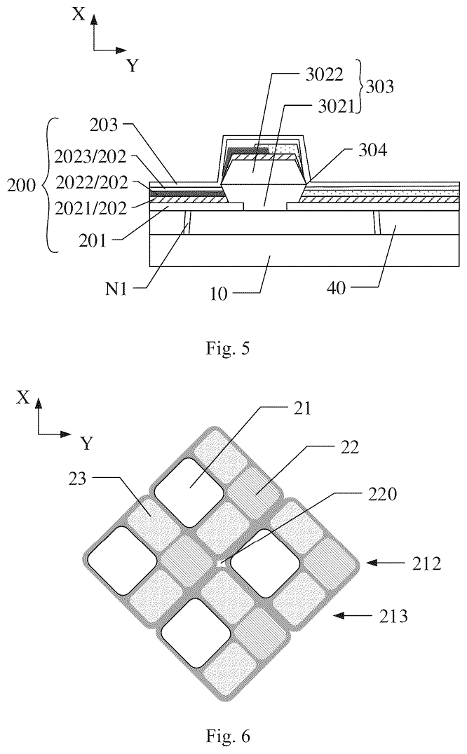

FIG. 5 is a cross-sectional view of still another display substrate provided by at least one embodiment of the present disclosure.

For example, the display substrate shown in FIG. 5 differs from the display substrate 01 in that the structure of the second sub-defining portion 3022 in the first defining portion 303 is different, the remaining structures are the same or similar, and no details will be repeated here. As shown in FIG. 5, a surface 3023 of the second sub-defining portion 3022 that is away from the base substrate 10 includes a flat surface parallel to the base substrate 10. For example, a cross section of the second sub-defining portion 3022 that is sectioned by a plane perpendicular to the extension direction of the first defining portion 303 has a shape of trapezoid, and the trapezoid has a lower base closer to the base substrate 10 than an upper base. Of course, the embodiment of the present disclosure is not limited thereto, for example, the shape of the second sub-defining portion 3022 may be set according to design requirements.

FIG. 6 is a partial schematic plan view of a display substrate provided by at least one embodiment of the present disclosure.

For example, as shown in FIG. 6, the plurality of sub-pixels 20 includes a plurality of first color sub-pixels 21, a plurality of second color sub-pixels 22, and a plurality of third color sub-pixels 23, the plurality of sub-pixels 20 is arranged as a plurality of first sub-pixel groups 212 and a plurality of second sub-pixel groups 213 arranged alternately along a first arrangement direction Y; the first sub-pixel group 212 includes first color sub-pixels 21 and second color sub-pixels 22 arranged alternately along a second arrangement direction Y, the second sub-pixel group 213 includes third color sub-pixels 23 arranged along the second arrangement direction Y, and the first arrangement direction X intersects with the second arrangement direction Y. For example, the first arrangement direction may be the X direction shown in FIG. 2, the second arrangement direction may be the Y direction shown in FIG. 2, and the first arrangement direction may be interchanged with the second arrangement direction. Here, for convenience of illustration, the first arrangement direction and the first direction adopt the same sign, while the second arrangement direction and the second direction adopt the same sign. For example, an included angle between the first arrangement direction and the second arrangement direction may be 80 degrees to 120 degrees. For example, the first arrangement direction is perpendicular to the second arrangement direction. For example, pixel arrangement shown in FIG. 6 may be a blue diamond pixel arrangement. Of course, the embodiment of the present disclosure is not limited thereto, and may also be other pixel arrangement, for example, triangular arrangement, delta arrangement, mosaic arrangement, etc.

For example, as shown in FIG. 6, the first sub-pixel group 212 and the second sub-pixel group 213 are shifted from each other in the second arrangement direction Y, each first color sub-pixel 21 among at least some first color sub-pixels 21 is surrounded by eight sub-pixels, and the eight sub-pixels include third color sub-pixels 23 and second color sub-pixels 22 alternately arranged. For example, four third color sub-pixels 23 are arranged respectively in directions with angles of 45°, 135°, 225° and 315° from a center of a light-emitting region of the first color sub-pixel 21.

For example, as shown in FIG. 2 and FIG. 6, one first defining portion 303 is provided between adjacent sub-pixels 20 to disconnect at least one film layer in the light-emitting functional layer 202 between adjacent sub-pixels 20, so as to reduce risks of crosstalk and color mixing.

For example, as shown in FIG. 2 and FIG. 6, an orthographic projection of the first defining portion 303 surrounding the opening 301 of the sub-pixel 20 on the base substrate 10 has a shape of closed ring. By such arrangement, the light-emitting functional layer 202 of the sub-pixel 20 may be disconnected in a circumferential direction, to reduce risks of crosstalk and color mixing with adjacent sub-pixels 20. For example, the display substrate further includes a plurality of spacing portions 220, the spacing portion 220 is located between two adjacent second sub-pixel groups 213 and located between a first color sub-pixel 21 and a second color sub-pixel 22 adjacent to each other in the second arrangement direction Y. For example, each spacing portion 220 is surrounded by two third color sub-pixels 23 adjacent to each other in the first arrangement direction X, and the first color sub-pixel 21 and the second color sub-pixel 22 adjacent to each other in the second arrangement direction Y, but it is not limited thereto.

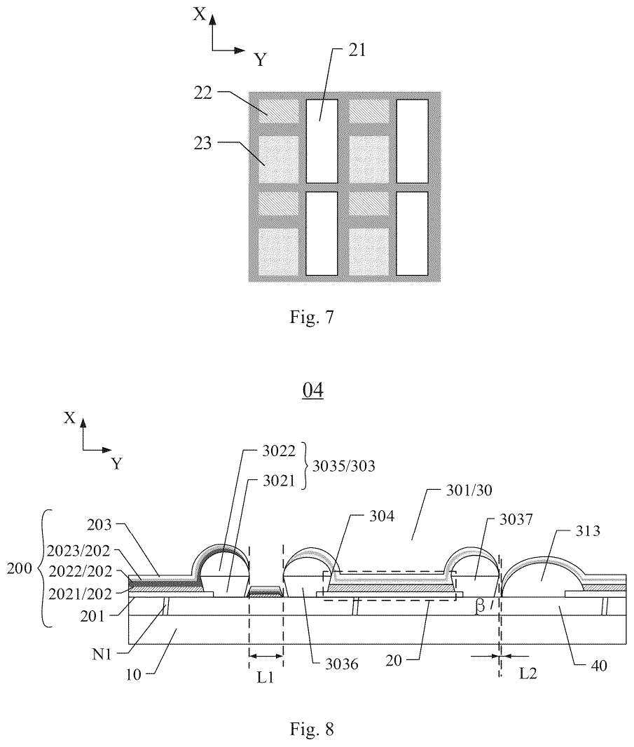

FIG. 7 is a partial schematic plan view of another display substrate provided by at least one embodiment of the present disclosure. The display substrate shown in FIG. 7 differs from the display substrate shown in FIG. 6 in different arrangement of the plurality of sub-pixels. Structures such as the base substrate, the pixel defining pattern, and the light-emitting element in the display substrate shown in FIG. 7 may have the same features as the structures, such as the base substrate, the pixel defining pattern, and the light-emitting element in the display substrate shown in FIG. 6, and no details will be repeated here.

For example, as shown in FIG. 7, the plurality of sub-pixels 20 includes a plurality of first color sub-pixels 21, a plurality of second color sub-pixels 22, and a plurality of third color sub-pixels 23. The plurality of sub-pixels 20 includes a plurality of pixel units arranged in an array along the first arrangement direction X and the second arrangement direction Y, each pixel unit includes one first color sub-pixel 21, one second color sub-pixel 22, and one third color sub-pixel 23. In respective pixel units, the second color sub-pixels 22 and the third color sub-pixels 23 are arranged alternately along the first arrangement direction X, and the first color sub-pixels 21 and the third color sub-pixels 23 are arranged alternately along the second arrangement direction Y.

For example, as shown in FIG. 7, one of the first color sub-pixel 21 and the second color sub-pixel 22 may be a red sub-pixel emitting red light, the other may be a blue sub-pixel emitting blue light, and the third color sub-pixel 23 may be a green sub-pixel emitting green light. For example, the first color sub-pixel 21 is a blue sub-pixel, and the second color sub-pixel 22 is a red sub-pixel. Of course, colors of light emitting by the first color sub-pixel, the second color sub-pixel, and the third color sub-pixel may be interchanged. For example, an area of a light-emitting region of the blue sub-pixel is larger than an area of a light-emitting region of the green sub-pixel, and an area of a light-emitting region of the green sub-pixel is larger than an area of a light-emitting region of the red sub-pixel. Of course, the embodiment of the present disclosure is not limited thereto, and the areas of the light-emitting regions of the sub-pixels with respective colors may be set according to actual product requirements.

For example, as shown in FIG. 7, the first arrangement direction may be the X direction shown in FIG. 2, the second arrangement direction may be the Y direction shown in FIG. 2, and the first arrangement direction may be interchanged with the second arrangement direction. Here, for convenience of illustration, the first arrangement direction and the first direction adopt the same sign, while the second arrangement direction and the second direction adopt the same sign. For example, pixel arrangement shown in FIG. 7 may be real RGB pixel arrangement.

For example, as shown in FIG. 2 and FIG. 7, an orthographic projection of the first defining portion 303 surrounding the opening 301 of the sub-pixel 20 on the base substrate 10 has a shape of closed ring. By such arrangement, the light-emitting functional layer 202 of the sub-pixel 20 may be disconnected in a circumferential direction, to reduce risks of crosstalk and color mixing with adjacent sub-pixels 20.

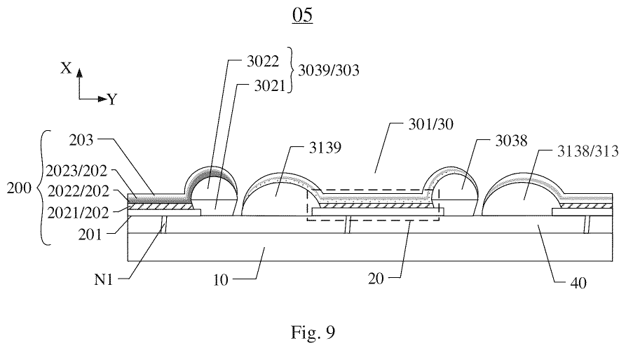

FIG. 8 is a cross-sectional view of another display substrate provided by at least one embodiment of the present disclosure, and FIG. 9 is a cross-sectional view of still another display substrate provided by at least one embodiment of the present disclosure.

For example, as shown in FIG. 8 and FIG. 9, both the display substrate 04 and the display substrate 05 include a base substrate 10 and a plurality of sub-pixels 20. The plurality of sub-pixels 20 is located on the base substrate 10, and each sub-pixel 20 among at least some sub-pixels 20 includes a light-emitting element 200. The light-emitting element 200 includes a light-emitting functional layer 202 as well as a first electrode 201 and a second electrode 203 located on both sides of the light-emitting functional layer 202 in the first direction X, and the first electrode 201 is located between the light-emitting functional layer 202 and the base substrate 10. The pixel defining pattern 30 includes a plurality of openings 301 and a defining portion 302 surrounding the plurality of openings 301, and at least a portion of the light-emitting element 200 is located within the opening 301. The defining portion 302 includes a first defining portion 303 located between adjacent light-emitting elements 200, a size, in a second direction Y, of a cross section of the first defining portion 303 as sectioned by a plane is a cross-sectional size, both the plane and the second direction Y are perpendicular to the extension direction of the first defining portion 303, and the second direction Y is perpendicular to the first direction X. In the first direction X, the cross-sectional size firstly increases and then decreases, the position with the maximum cross-sectional size is located at an isolation portion 304 of the first defining portion 303, and at least one layer of the light-emitting functional layer 202 is isolated at an edge of the isolation portion 304 that faces the light-emitting element 200.

For example, as shown in FIG. 8 and FIG. 9, second electrodes 203 of adjacent sub-pixels 20 are isolated at the edge of the isolation portion 304, the display substrate is more controllable during the fabrication process, which is favorable for simplifying the fabrication process of the display substrate while reducing risks of crosstalk and color mixing between adjacent sub-pixels 20. It should be noted that even if second electrodes 203 of adjacent sub-pixels 20 are isolated at the edge of the isolation portion 304 of the first defining portion 303, other portions of the second electrodes 203 of the adjacent sub-pixels 20 are connected with each other, so that signal transmission may be carried out between the second electrodes 203 of the adjacent sub-pixels 20. For example, as shown in FIG. 8 and FIG. 9, the cross section of the first defining portion 303 that is sectioned by the above-described plane includes a side edge located between the position with the maximum cross-sectional size and the base substrate 10, an included angle β between at least a portion of the side edge and the second direction Y is 100° to 110°, and a maximum size of the first sub-defining portion 3021 in the first direction X is 1 μm to 1.2 μm.

For example, as shown in FIG. 8 and FIG. 9, the cross section of the first defining portion 303 that is sectioned by the above-described plane includes an edge line located on a side of the position with the maximum cross-sectional size away from the base substrate 10, an included angle between a tangent line at a point connecting the edge line and the position with the maximum cross-sectional size and the second direction Y is 35° to 45°; and a maximum size of the second sub-defining portion 3022 in the first direction X is 0.9 μm to 1.1 μm.

For example, as shown in FIG. 8 and FIG. 9, the maximum sizes of the first sub-defining portion 3021 and the second sub-defining portion 3022 in the first direction X are both larger, and an included angle β between at least a portion of the above-described side edge of the first defining portion 303 and the second direction Y is greater, so that the first defining portion 303 has strong disconnection capability, which is favorable for disconnecting the light-emitting functional layer 202 and the second electrode 203 of the sub-pixel 20 together.

For example, as shown in FIG. 8 and FIG. 9, the included angle β between at least a portion of the above-described side edge of the first defining portion 303 and the second direction Y may be at least one of 100° to 105°, 102° to 105°, 104° to 106°, 107° to 109°, and 103° to 108°, but it is not limited thereto. For example, the maximum size of the first sub-defining portion 3021 in the first direction X is at least one of 1.05 μm to 1.1 μm, 1.1 μm to 1.15 μm, and 1.15 μm to 1.2 μm, but it is not limited thereto.

For example, as shown in FIG. 8 and FIG. 9, the included angle between the tangent line and the second direction Y may be at least one of 35° to 40°, 36° to 42°, 37° to 43°, and 38° to 44°, the tangent line is the tangent line at the point connecting the above-described edge line of the cross section of the first defining portion 303 that is sectioned by the above-described plane and the position with the maximum cross-sectional size, but it is not limited thereto. For example, the maximum size of the second sub-defining portion 3022 in the first direction X may be at least one of 0.95 μm to 1.05 μm, 0.95 μm to 1.10 μm, 0.98 μm to 1.08 μm, and 0.99 μm to 1.1 μm, but it is not limited thereto.

For example, as shown in FIG. 8 and FIG. 9, the defining portion 302 further includes a second defining portion 313, the second defining portion 313 is closely adjacent to the edge of the light-emitting region of the light-emitting element 200, and an extension direction of the second defining portion 313 is the same as the extension direction of the first defining portion 303.

For example, as shown in FIG. 8 and FIG. 9, the second defining portion 313 may not be used for disconnecting the light-emitting functional layer 202 and the second electrode 203 of the sub-pixel 20, but may rather surround a portion of the edge arranged at the opening of the sub-pixel 20 and may be used for defining the light-emitting region of the sub-pixel 20. For example, the first defining portion 303 and the second defining portion 313 surrounding an opening 301 of the same sub-pixel 20 are connected with each other, and orthographic projections thereof on the base substrate 10 have a shape of closed ring.

For example, as shown in FIG. 8 and FIG. 9, in the first direction X, a size of the second defining portion 313 is smaller than a size of the first defining portion 303, and the second defining portion 313 and the second sub-defining portion 3022 are made of the same material. For example, an edge line in a cross section of the second defining portion 313 away from the base substrate 10 that is sectioned by a plane may have an arc shape, the arc-shaped edge line has a relatively mild trend, and the plane is perpendicular to the extension direction of the second defining portion 313. For example, when the second defining portion 313 is made of the same material as that of the second sub-defining portion 3022, the second defining portion 313 and the second sub-defining portion 3022 may be arranged in the same layer, and formed by using the same patterning process, thereby simplifying the fabrication process.

For example, as shown in FIG. 8 and FIG. 9, in the first direction X, the size of the second defining portion 313 is larger than the size of the second sub-defining portion 3022, which may better define the light-emitting region of the light-emitting element 200. For example, in the first direction X, the size of the second defining portion 313 may be at least one of 1.2 to 1.8 times, 1.2 to 1.5 times, 1.3 to 1.6 times, and 1.4 to 1.7 times the size of the second sub-defining portion 3022, but it is not limited thereto.

For example, as shown in FIG. 8 and FIG. 9, the maximum size of the first defining portion 303 in the second direction Y may be 5 μm to 9 μm, for example, may be at least one of 5 μm to 8 μm, 5 μm to 7 μm, 5.5 μm to 7.5 μm, 6.5 μm to 8.5 μm, and 7.5 μm to 8.5 μm, but it is not limited thereto.

For example, as shown in FIG. 8, edges of light-emitting regions of at least some sub-pixels 20 include a first edge closely adjacent to the first defining portion 303, and first edges of light-emitting regions of two adjacent sub-pixels 20 are arranged at least partially opposite to each other, and orthographic projections of first defining portions 303 respectively closely adjacent to first edges of light-emitting regions of two adjacent sub-pixels 20 on the base substrate 10 have a first interval therebetween.

For example, as shown in FIG. 8, a first defining portion 3035 and a first defining portion 3036 are respectively closely adjacent to first edges of light-emitting regions of two adjacent sub-pixels 20, and the first interval between orthographic projections of the first defining portion 3035 and the first defining portion 3036 on the base substrate 10 is L1.

For example, as shown in FIG. 8 and FIG. 9, edges of light-emitting regions 202 of at least some sub-pixels 20 further include a second edge closely adjacent to the second defining portion 313, the second edge of a light-emitting region 202 of a certain sub-pixel 20 is arranged at least partially opposite to the first edge of a light-emitting region of a sub-pixel 20 adjacent to the certain sub-pixel, and orthographic projections of defining portions respectively closely adjacent to the second edge and the first edge on the base substrate 10 have a second interval.

For example, as shown in FIG. 8, the second defining portion 313 closely adjacent to the second edge of the light-emitting region of a certain sub-pixel 20 is arranged opposite to the first defining portion 3037 closely adjacent to the first edge of the light-emitting region of a sub-pixel 20 adjacent to the certain sub-pixel, and the second defining portion 313 and the first defining portion 3037 have the second interval L2.

For example, as shown in FIG. 8, the first interval L1 between the first defining portion 3035 and the first defining portion 3036 adjacent to each other is beneficial to disconnect at least one film layer of the light-emitting functional layer 202 and the second electrode 203 between the first defining portion 3035 and the first defining portion 3036; and the second interval L2 between the second defining portion 313 and the first defining portion 3037 is beneficial to disconnect at least one film layer of the light-emitting functional layer 202 and the second electrode 203 between the second defining portion 313 and the first defining portion 3037; so that arrangement of the first interval LI and the second interval L2 is favorable for enhancing an isolation effect of at least one film layer of the light-emitting functional layer 202 and the second electrode 203, and reducing a risk of crosstalk between adjacent sub-pixels 20.

For example, as shown in FIG. 8, in the arrangement direction of sub-pixels 20, a size of the first interval L1 is larger than a size of the second interval L2.

For example, as shown in FIG. 8, two adjacent sub-pixels 20 arranged along the second direction Y are configured to emit light of different colors, in order to reduce a risk of crosstalk between adjacent sub-pixels 20 emitting light of different colors, the first defining portion 3035 and the first defining portion 3036 may be provided at an interval between the two adjacent sub-pixels 20, or, the first defining portion 3037 and the second defining portion 313 may also be provided at an interval between the two adjacent sub-pixels 20.

For example, as shown in FIG. 8, an edge of the light-emitting region 202 of the same sub-pixel 20 is formed by connecting the first edge and the second edge, and the first defining portion 303 is provided closely adjacent to the first edge. When one of two opposite edges of light-emitting regions of two adjacent sub-pixels 20 includes the first edge, at least one film layer of the light-emitting functional layer 202 and the second electrode 203 between the two adjacent sub-pixels 20 may be isolated, thereby reducing a risk of crosstalk. For example, two opposite edges of light-emitting regions of two adjacent sub-pixels 20 each include the first edge, such as the first edge closely adjacent to the first defining portion 3035 and the first edge closely adjacent to the first defining portion 3036 in FIG. 8, resulting a better isolation effect on at least one film layer of the light-emitting functional layer 202 and the second electrode 203 between the two adjacent sub-pixels 20, but it is not limited thereto.

For example, as shown in FIG. 8, when at least one film layer of the light-emitting functional layer 202 and the second electrode 203 are isolated by the first edge of the first defining portion 3035 and the first edge of the first defining portion 3036 closely adjacent thereto, a portion of film layer in the at least one film layer of the light-emitting functional layer 202 or a portion of the second electrode 203 may also be located between the first defining portion 3035 and the first defining portion 3036, for example, may fall on a side of the structural layer 40 that is away from the base substrate 10, but it is not limited thereto.

FIG. 10 is a partial schematic plan view of a display substrate corresponding to FIG. 8 provided by at least one embodiment of the present disclosure; and FIG. 11 is a partial schematic plan view of still another display substrate corresponding to FIG. 8 provided by at least one embodiment of the present disclosure. For example, FIG. 8 corresponds to cross-sectional schematic diagrams respectively sectioned by dashed lines in FIG. 10 and FIG. 11.

For example, as shown in FIG. 10, the plurality of sub-pixels includes a plurality of first color sub-pixels 21, a plurality of second color sub-pixels 22, and a plurality of third color sub-pixels 23, the plurality of sub-pixels is arranged as a plurality of first sub-pixel groups 212 and a plurality of second sub-pixel groups 213 arranged alternately along a first arrangement direction Y, the first sub-pixel group 212 includes first color sub-pixels 21 and second color sub-pixels 22 arranged alternately along a second arrangement direction Y, the second sub-pixel group 213 includes third color sub-pixels 23 arranged along the second arrangement direction Y, and the first arrangement direction X intersects with the second arrangement direction Y. For example, the first arrangement direction may be an X direction shown in FIG. 2, the second arrangement direction may be a Y direction shown in FIG. 2, and the first arrangement direction may be interchanged with the second arrangement direction. For example, pixel arrangement shown in FIG. 10 may be the same as pixel arrangement shown in FIG. 6, for which relevant illustrations of the above-described embodiments may be referred to. For example, as compared with the display substrate shown in FIG. 6, in the display substrate shown in FIG. 10, the structural form of the defining portion 303 arranged in the circumferential direction of the light-emitting region of the sub-pixel is different.

For example, as shown in FIG. 8 and FIG. 10, an orthographic projection of the first defining portion 303 surrounding the opening 301 of the pixel defining pattern on the base substrate 10 has a shape of non-closed ring, and second electrodes 203 of adjacent light-emitting elements 200 are at least partially connected at a notch of the non-closed ring.

For example, as shown in FIG. 8 and FIG. 10, an orthographic projection of a light-emitting region of each sub-pixel 20 on the base substrate 10 has a shape of approximate rectangle, and among edges of the light-emitting region 202 of each sub-pixel 20, a size of the first edge in the circumferential direction is larger than a size of the second edge in the circumferential direction, so that an area of an orthographic projection of the first defining portion 303 closely adjacent to the edge of the light-emitting region 202 of the sub-pixel 20 on the base substrate 10 is larger than an area of an orthographic projection of the second defining portion 313 closely adjacent to the edge of the light-emitting region 202 of the sub-pixel 20 on the base substrate 10. For example, the area of the orthographic projection of the first defining portion 303 closely adjacent to the edge of the light-emitting region 202 of the sub-pixel 20 on the base substrate 10 is 2.5 to 3.5 times, for example, may be 3 times, 3.2 times, or 3.5 times, etc. that of the area of the orthographic projection of the second defining portion 313 closely adjacent to the edge of the light-emitting region 202 of the sub-pixel 20 on the base substrate 10, but it is not limited thereto. For example, an orthographic projection of the first defining portion 303 surrounding the opening 301 on the base substrate 10 has a “U” shape, and all “U” shapes have the same opening orientation, which is an M direction shown in FIG. 10. For example, the M direction may be a direction that forms an included angle of 45° to 50° with the first arrangement direction X, but it is not limited thereto. An N direction intersects with the M direction, for example, an included angle between the N direction and the M direction may be 80 degrees to 120 degrees, for example, the N direction is perpendicular to the M direction.

For example, as shown in FIG. 8 and FIG. 10, in the N direction, adjacent and opposite edges of light-emitting regions 202 of two adjacent sub-pixels 20 are each provided with the first defining portion 303, and there is a first distance between adjacent first defining portions 303. In the M direction, one first defining portion 303 and one second defining portion 313 are provided between adjacent and opposite edges of light-emitting regions 202 of two adjacent sub-pixels 20, and there is a second distance between the one first defining portion 303 and the one second defining portion 313. For example, the second electrode 203 of the light-emitting element 200 is provided with the second defining portion 313 at a notch of the above-described non-closed ring, and the second electrode 203 of the light-emitting element 200 of a certain sub-pixel 20 is continuously provided at the second defining portion 313, and is connected with the second electrode 203 of a sub-pixel 20 adjacent to the certain sub-pixel, so that second electrodes 203 of the plurality of sub-pixels 20 may be connected as a whole, but it is not limited thereto.

For example, the display substrate shown in FIG. 11 differs from the display substrate shown in FIG. 10 in that an arrangement mode of the plurality of sub-pixels is different. For example, the arrangement mode of the plurality of sub-pixels in the display substrate shown in FIG. 11 may be the same as the arrangement mode of the plurality of sub-pixels in the display substrate shown in FIG. 7, but it is not limited thereto.

For example, as shown in FIG. 11, the plurality of sub-pixels 20 includes a plurality of first color sub-pixels 21, a plurality of second color sub-pixels 22, and a plurality of third color sub-pixels 23. The plurality of sub-pixels 20 includes a plurality of pixel units arranged in an array along the first arrangement direction X and the second arrangement direction Y; each pixel unit includes one first color sub-pixel 21, one second color sub-pixel 22, and one third color sub-pixel 23. In respective pixel units, the second color sub-pixels 22 and the third color sub-pixels 23 are arranged alternately along the first arrangement direction X, the first color sub-pixels 21 and the third color sub-pixels 23 are arranged alternately along the second arrangement direction Y, and the first arrangement direction X intersects with the second arrangement direction Y.

For example, as shown in FIG. 8 and FIG. 11, an orthographic projection of the first defining portion 303 surrounding the opening 301 of the pixel defining pattern on the base substrate 10 has a “U” shape, and all “U” shapes have the same opening orientation, which is the Y direction shown in FIG. 11. In the X direction, adjacent and opposite edges of light-emitting regions 202 of two adjacent sub-pixels 20 are each provided with the first defining portion 303, and there is a first distance between adjacent first defining portions 303. In the Y direction, one first defining portion 303 and one second defining portion 313 are provided between adjacent and opposite edges of light-emitting regions 202 of two adjacent sub-pixels 20, and there is a second distance between the one first defining portion 303 and the one second defining portion 313. For example, the second defining portion 313 is provided at a notch of the above-described non-closed ring, and the second electrode 203 of the light-emitting element 200 of the certain sub-pixel 20 is connected with the second electrode 203 of the sub-pixel 20 adjacent to certain sub-pixel on the second defining portion 313 at the notch of the ring, so that second electrodes 203 of the plurality of sub-pixels 20 may be connected as a whole, but it is not limited thereto.

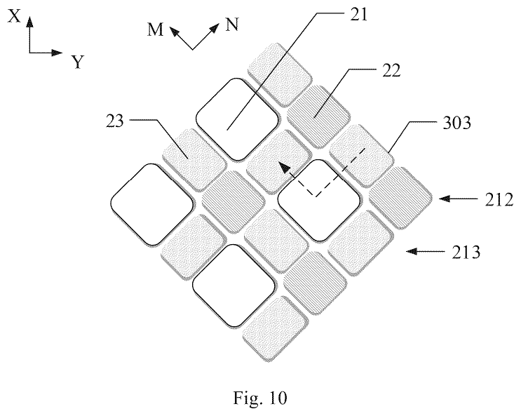

FIG. 12 is a partial schematic plan view of still another display substrate corresponding to FIG. 8 provided by at least one embodiment of the present disclosure; and FIG. 13 is a partial schematic plan view of still another display substrate corresponding to FIG. 8 provided by at least one embodiment of the present disclosure. For example, FIG. 8 corresponds to the cross-sectional schematic diagrams respectively sectioned by dashed lines in FIG. 12 and FIG. 13.

For example, an arrangement mode of the plurality of sub-pixels in the display substrate shown in FIG. 12 may be the same as the arrangement mode of the plurality of sub-pixels in the display substrate shown in FIG. 10. For example, the display substrate shown in FIG. 12 differs from the display substrate shown in FIG. 10 in the structural form of the defining portion closely adjacent to the light-emitting region of the sub-pixel.

For example, as shown in FIG. 8 and FIG. 12, an orthographic projection of the first defining portion 303 surrounding the opening 301 of the pixel defining pattern on the base substrate 10 has a “U” shape, and all “U” shapes have the same opening orientation, which is the N direction shown in FIG. 12. In the M direction, adjacent and opposite edges of light-emitting regions 202 of two adjacent sub-pixels 20 are each provided with the first defining portion 303, and there is a first distance between adjacent first defining portions 303. In the N direction, one first defining portion 303 and one second defining portion 313 are provided between adjacent and opposite edges of light-emitting regions 202 of two adjacent sub-pixels 20, and there is a second distance between the one first defining portion 303 and the one second defining portion 313. For example, the second defining portion 313 is provided at a notch of the above-described non-closed ring, and the second electrode 203 of the light-emitting element 200 of the sub-pixel 20 is connected with the second electrode 203 of an adjacent sub-pixel 20 at the notch of the ring, so that second electrodes 203 of the plurality of sub-pixels 20 may be connected as a whole, but it is not limited thereto.

For example, an arrangement mode of the plurality of sub-pixels in the display substrate shown in FIG. 13 may be the same as the arrangement mode of the plurality of sub-pixels in the display substrate shown in FIG. 11. For example, the display substrate shown in FIG. 13 differs from the display substrate shown in FIG. 11 in the structural form of the defining portion closely adjacent to the light-emitting region of the sub-pixel.

For example, as shown in FIG. 13, an orthographic projection of the first defining portion 303 surrounding the opening 301 of the pixel defining pattern on the base substrate 10 has a “U” shape, and “U” shapes of different sub-pixels may have different opening orientations. For example, an opening orientation of an orthographic projection having “U” shape of the first defining portion 303 surrounding the first color sub-pixel 21 on the base substrate 10 is the Y direction, and opening orientations of orthographic projections having “U” shapes of first defining portions 303 surrounding the second color sub-pixel 22 and the third color sub-pixel 23 which are located in the same column along the X direction on the base substrate 10 are the X direction, but it is not limited thereto. For example, in the X direction, adjacent and opposite edges of light-emitting regions 202 of adjacent first color sub-pixels 21 are each provided with the first defining portion 303, and there is a first distance between adjacent first defining portions 303; one first defining portion 303 and one second defining portion 313 are provided between adjacent and opposite edges of light-emitting regions 202 of the second color sub-pixel 22 and the third color sub-pixel 23 adjacent to each other, and there is a second distance between the one first defining portion 303 and the one second defining portion 313. For example, the second defining portion 313 is provided at a notch of the above-described non-closed ring, and the second electrode 203 of the light-emitting element 200 of the certain sub-pixel 20 is continuously provided at the second defining portion 313, and is connected with the second electrode 203 of the sub-pixel 20 adjacent to the certain sub-pixel, so that second electrodes 203 of the plurality of sub-pixels 20 may be connected as a whole, but it is not limited thereto.

For example, as shown in FIG. 9, two adjacent sub-pixels 20 arranged along the second direction Y are configured to emit light of different colors. For example, one of two opposite edges of light-emitting regions of two adjacent sub-pixels 20 includes a first edge, so that the light-emitting functional layer 202 and the second electrode 203 between the two adjacent sub-pixels 20 are isolated, to reduce a risk of crosstalk. For example, as shown in FIG. 9, the first defining portion 3038 closely adjacent to an edge of a light-emitting region of the same sub-pixel 20 is spaced apart from the second defining portion 3138 closely adjacent to an edge of a light-emitting region of an adjacent sub-pixel, and the second defining portion 3139 closely adjacent to the edge of the light-emitting region of the same sub-pixel 20 is spaced apart from the first defining portion 3039 closely adjacent to the edge of the light-emitting region of the adjacent sub-pixel, but it is not limited thereto.

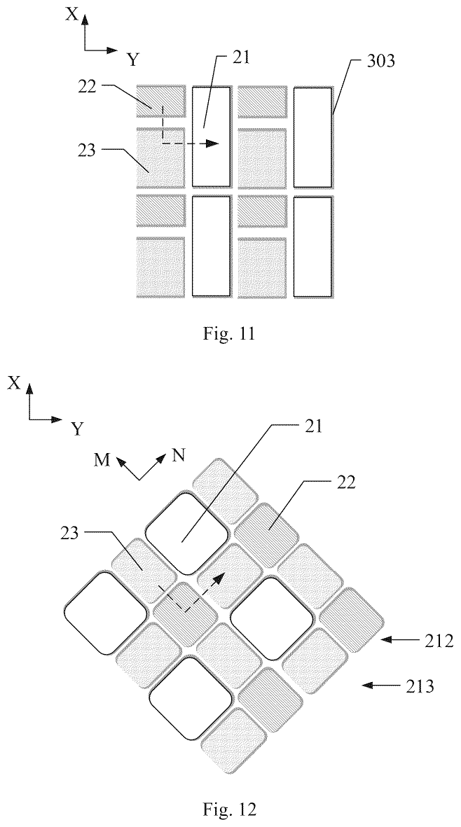

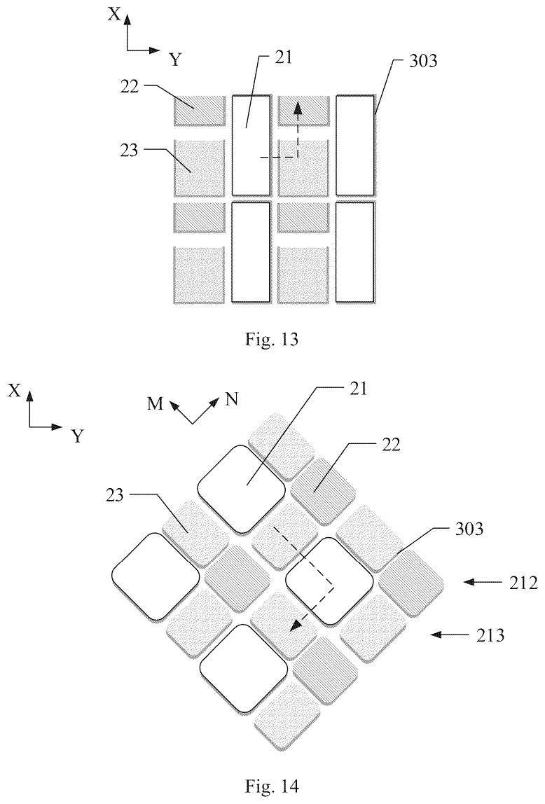

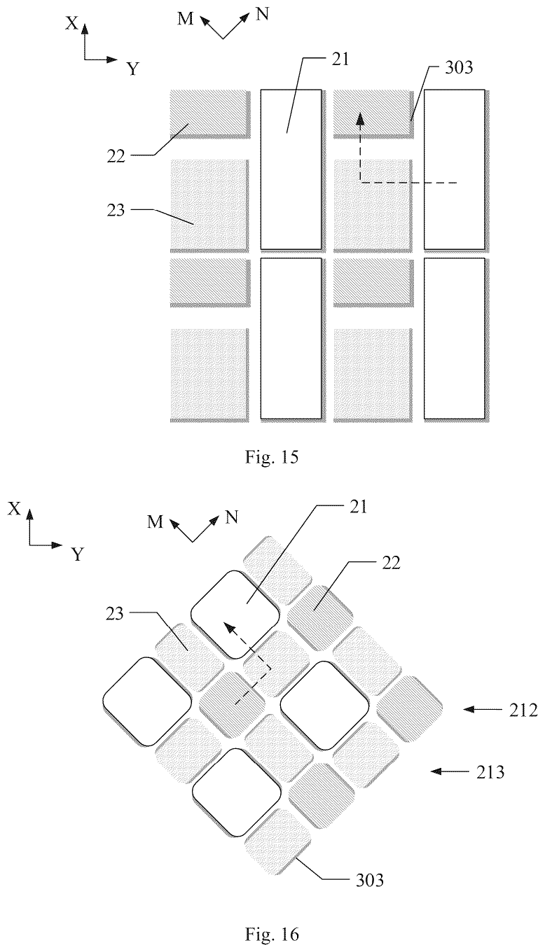

FIG. 14 is a partial schematic plan view of a display substrate corresponding to FIG. 9 provided by at least one embodiment of the present disclosure, and FIG. 15 is a partial schematic plan view of still another display substrate corresponding to FIG. 9 provided by at least one embodiment of the present disclosure. For example, FIG. 9 corresponds to the cross-sectional schematic diagrams respectively sectioned by dashed lines in FIG. 14 and FIG. 15.

For example, an arrangement mode of the plurality of sub-pixels in the display substrate shown in FIG. 14 may be the same as the arrangement mode of the plurality of sub-pixels in the display substrate shown in FIG. 10. For example, the display substrate shown in FIG. 14 differs from the display substrate shown in FIG. 10 in the structural form of the defining portion closely adjacent to the light-emitting region of the sub-pixel.

For example, as shown in FIG. 9 and FIG. 14, an orthographic projection of the first defining portion 303 surrounding the opening 301 of the pixel defining pattern on the base substrate 10 has a “V” shape, and all “V” shapes have the same opening orientation, which is the X direction shown in FIG. 14. For example, in the M direction or in the N direction, one first defining portion 303 and one second defining portion 313 are provided between adjacent and opposite edges of light-emitting regions 202 of two adjacent sub-pixels 20, and there is a second distance between the one first defining portion 303 and the one second defining portion 313. For example, the second defining portion 313 is disposed at an opening having the above-described “V” shape, the second electrode 203 of the light-emitting element 200 of the sub-pixel 20 is continuously arranged at the second defining portion 313, and is connected with the second electrode 203 of an adjacent sub-pixel 20, so that second electrodes 203 of the plurality of sub-pixels 20 may be connected as a whole, but it is not limited thereto.

Of course, the embodiment of the present disclosure is not limited thereto; for example, the orthographic projection of the first defining portion 303 surrounding the opening 301 of the pixel defining pattern on the base substrate 10 has a “V” shape, and the opening orientation of the “V” shape may also be the Y direction shown in FIG. 14, which may be specifically set according to design requirements.

For example, an arrangement mode of the plurality of sub-pixels in the display substrate shown in FIG. 15 may be the same as the arrangement mode of the plurality of sub-pixels in the display substrate shown in FIG. 11. For example, the display substrate shown in FIG. 15 differs from the display substrate shown in FIG. 11 in the structural form of the defining portion closely adjacent to the light-emitting region of the sub-pixel.

For example, as shown in FIG. 9 and FIG. 15, an orthographic projection of the first defining portion 303 surrounding the opening 301 of the pixel defining pattern on the base substrate 10 has a “V” shape, and opening orientations of all “V” shapes may be the M direction shown in FIG. 15. For example, in the X direction or in the Y direction, one first defining portion 303 and one second defining portion 313 are disposed between adjacent and opposite edges of light-emitting regions 202 of two adjacent sub-pixels 20, and there is a second distance between the one first defining portion 303 and the one second defining portion 313. For example, the second defining portion 313 is provided at an opening having the above-described “V” shape, and the second electrode 203 of the light-emitting element 200 of the sub-pixel 20 is at least partially connected with the second electrode 203 of an adjacent sub-pixel 20, so that second electrodes 203 of the plurality of sub-pixels 20 may be connected as a whole, but it is not limited thereto.

Of course, the embodiment of the present disclosure is not limited thereto; for example, the orthographic projection of the first defining portion 303 surrounding the opening 301 of the pixel defining pattern on the base substrate 10 has a “V” shape, and the opening orientation of the “V” shape may also be the N direction shown in FIG. 15, which may be specifically set according to design requirements.

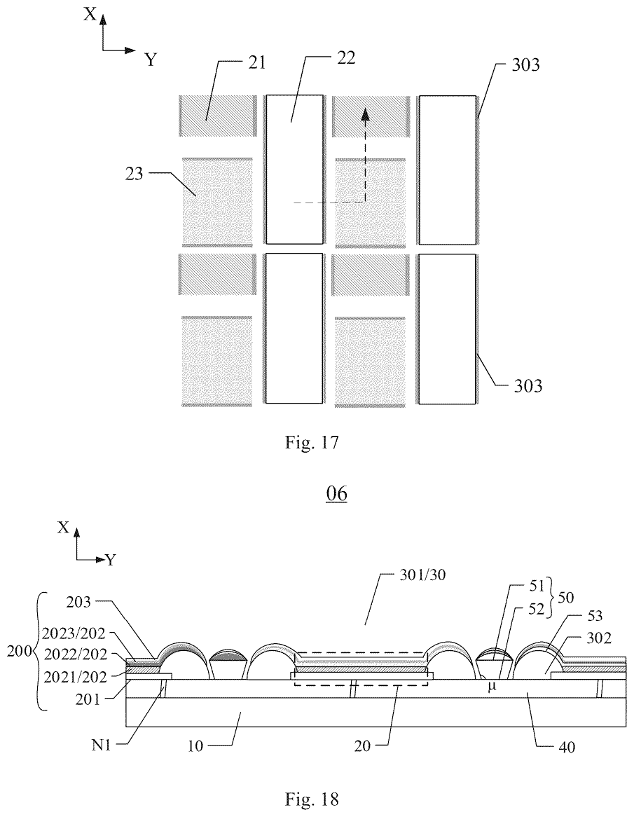

FIG. 16 is a partial schematic plan view of still another display substrate corresponding to FIG. 9 provided by at least one embodiment of the present disclosure; and FIG. 17 is a partial schematic plan view of still another display substrate corresponding to FIG. 9 provided by at least one embodiment of the present disclosure. For example, FIG. 9 corresponds to the cross-sectional schematic diagrams respectively sectioned by dashed lines in FIG. 16 and FIG. 17.

For example, an arrangement mode of the plurality of sub-pixels in the display substrate shown in FIG. 16 may be the same as the arrangement mode of the plurality of sub-pixels in the display substrate shown in FIG. 10. For example, the display substrate shown in FIG. 16 differs from the display substrate shown in FIG. 10 in the structural form of the defining portion closely adjacent to the light-emitting region of the sub-pixel.

For example, as shown in FIG. 9 and FIG. 16, an orthographic projection of a first defining portion 303 surrounding the same opening 301 on the base substrate 10 has a“=” shape. For example, in the M direction or in the N direction, one first defining portion 303 and one second defining portion 313 are provided between two adjacent and opposite edges of light-emitting regions of sub-pixels 20, and there is a second distance between the one first defining portion 303 and the one second defining portion 313. For example, second electrodes 203 of light-emitting elements 200 of adjacent sub-pixels 20 are at least partially connected, so that second electrodes 203 of the plurality of sub-pixels 20 may be connected as a whole, but it is not limited thereto.

For example, an arrangement mode of the plurality of sub-pixels in the display substrate shown in FIG. 17 may be the same as the arrangement mode of the plurality of sub-pixels in the display substrate shown in FIG. 11. For example, the display substrate shown in FIG. 17 differs from the display substrate shown in FIG. 11 in the structural form of the defining portion closely adjacent to the light-emitting region of the sub-pixel.

For example, as shown in FIG. 17, an orthographic projection of the first defining portion 303 surrounding the same opening 301 on the base substrate 10 has a “=” shape. For example, in the X direction, two opposite edges of the light-emitting region of the third color sub-pixel 23 are each provided with the first defining portion 303. For example, in the Y direction, two adjacent and opposite edges of light-emitting regions of the first color sub-pixel 21 and the second color sub-pixel 22 are each provided with the second defining portions 313, but it is not limited thereto. For example, in the X direction, one first defining portion 303 and one second defining portion 313 are provided between light-emitting regions of adjacent sub-pixels 20 (e.g., the first color sub-pixel 21 and the third color sub-pixel 23 adjacent to each other), and there is a second distance between the one first defining portion 303 and the one second defining portion 313. For example, in the Y direction, adjacent and opposite edges of light-emitting regions of adjacent sub-pixels (e.g. the first color sub-pixel 21 and the third color sub-pixel 23 adjacent to each other) are each provided with the first defining portion 303, and there is a first distance between adjacent first defining portions 303. For example, second electrodes 203 of light-emitting elements 200 of adjacent sub-pixels 20 are at least partially connected with each other, so that second electrodes 203 of the plurality of sub-pixels 20 may be connected as a whole, but it is not limited thereto.

FIG. 18 is a cross-sectional view of still another display substrate provided by at least one embodiment of the present disclosure.

As shown in FIG. 18, the display substrate 06 includes a base substrate 10, a plurality of sub-pixels 20, and a pixel defining pattern 30. The plurality of sub-pixels 20 is located on the base substrate 10, each sub-pixel 20 among at least some sub-pixels 20 includes a light-emitting element 200, the light-emitting element 200 includes a light-emitting functional layer 202 as well as a first electrode 201 and a second electrode 203 located on both sides of the light-emitting functional layer 202 in the first direction X, the first electrode 201 is located between the light-emitting functional layer 202 and the base substrate 10; the pixel defining pattern 30 includes a plurality of openings 301 and a defining portion 302 surrounding the plurality of openings 301, and at least a portion of the light-emitting element 200 is located in the opening 301.

For example, as shown in FIG. 18, the light-emitting functional layer 202 may include a plurality of film layers, for example, a hole transport layer 2021, a light-emitting layer 2022, and an electron transport layer 2023, the hole transport layer 2021 and the electron transport layer 2023 are respectively located on both sides of the light-emitting layer 2022. For example, the first electrode 201 may be an anode, and the second electrode 203 may be a cathode. For example, the anode may be made of a transparent conductive material having high work functions, for example, indium tin oxide (ITO), but it is not limited thereto. For example, the opening 301 of the pixel defining pattern 30 is configured to define a light-emitting region of the light-emitting element 200. For example, the light-emitting element 200 may include a portion located in the opening 301, and a portion overlapping with the defining portion 302 in a direction perpendicular to the base substrate 10. For example, as shown in FIG. 18, the opening 301 of the pixel defining pattern 30 is configured to expose the first electrode 201 of the light-emitting element 200, and the exposed first electrode 201 is at least partially in contact with the light-emitting functional layer 202 in the light-emitting element 200.

As shown in FIG. 18, the display substrate 06 further includes an isolation structure 50 located between defining portions 302 respectively closely adjacent to two adjacent openings, and a material of the isolation structure 50 is different from a material of the defining portion 302. For example, the above-described two adjacent defining portions 302 are spaced apart and respectively surround openings of light-emitting regions of two adjacent sub-pixels. For example, the material of the defining portion 302 may include polyimide resin and propylene glycol monomethyl ether acetate, but it is not limited thereto. For example, in some embodiments, the material of the defining portion 302 may also include acrylic or polyethylene terephthalate, etc. For example, the material of the isolation structure 50 may include phenolic resin and propylene glycol monomethyl ether acetate, etc., so that impact of the isolation structure 50 and the defining portion 302 on each other is relatively small during the fabrication process. For example, when the isolation structure 50 and the defining portion 302 are formed by using a wet etching process, the isolation structure 50 and the defining portion 302 made of different materials may have different etch selectivities, but it is not limited thereto.

As shown in FIG. 18, in a second direction Y, a maximum size of a first edge line 51 is larger than a maximum size of a second edge line 52, the first edge line 51 is an edge line of a cross section, as sectioned by a plane, of the isolation structure 50 away from the base substrate 10, and the second edge line 52 is an edge line of the cross section close to the base substrate 10; both the plane and the second direction Y are perpendicular to an extension direction of the defining portion 302, and the second direction Y is perpendicular to a first direction X. For example, a surface of the isolation structure 50 that is away from the base substrate 10 may not be an absolute plane, for example, may include a partially convex or concave structure, so that the corresponding first edge line 51 may not be an absolute straight line, for example, may include a portion of a curve, etc., which will not be limited in the embodiments of the present disclosure.

As shown in FIG. 18, between at least two adjacent light-emitting elements 200, at least one layer of the light-emitting functional layer 202 is isolated at the edge of the isolation structure 50, and at least a portion of the second electrode 203 corresponding to the at least one certain light-emitting element 200 extends from the light-emitting region of the certain light-emitting element 200 to the light-emitting region of at least one light-emitting element 200 adjacent to the certain light-emitting element 200. For example, between at least two adjacent light-emitting elements 200, the second electrode 203 corresponding to at least one certain light-emitting element 200 may be a portion connected with the second electrode 203 of at least one of light-emitting elements 200 adjacent to the at least one certain light-emitting element, so that the second electrode 203 covering the light-emitting region of the at least one certain light-emitting element 200 and the second electrode 203 covering the light-emitting region of the at least one of light-emitting elements 200 adjacent to the at least one certain light-emitting element are connected as a whole. For example, as shown in FIG. 18, the second electrode 203 of the at least one light-emitting element 200 may further include another portion that is isolated at the edge of the isolation structure 50, and the another portion is isolated in a position facing the edge of the light-emitting element 200.

For example, as shown in FIG. 18, the cross section of the isolation structure 50 that is sectioned by the above-described plane has a shape of “trapezoid”, and the “trapezoid” has an upper bottom closer to the base substrate 10 than a lower bottom. For example, the first edge line 51 and the second edge line 52 of the cross section of the isolation structure 50 that is sectioned by the above-described plane both extend along the second direction Y, and a side edge located between the first edge line 51 and the second edge line 52 has a sharp included angle u with the first edge line 51. For example, the included angle μ may be 30° to 65°, for example, may be at least one of 30° to 60°, 40° to 50°, 45° to 55°, and 35° to 50°, but it is not limited thereto. For example, the first edge line 51 may have different included angles respectively with side edges located on both sides thereof, which may be set according to design requirements. Therefore, the isolation structure 50 may have good isolation effect on at least one layer of the light-emitting functional layer 202 and the second electrode 203.

For example, as shown in FIG. 18, one isolation structure 50 is provided between two defining portions 302 located between adjacent sub-pixels 20, and the isolation structure 50 is respectively spaced apart from the two defining portions 302, which may further enhance the isolation effect on at least one layer of the light-emitting functional layer 202 and the second electrode 203. However, the embodiment of the present disclosure is not limited thereto, for example, the number of isolation structures 50 provided between two adjacent defining portions 302 may also be a plural, to enhance the isolation effect on at least one layer of the light-emitting functional layer 202 and the second electrode 203, which may be set according to design requirements.

In the embodiment of the present disclosure, the isolation structure 50 is provided between two defining portions 302 located between adjacent sub-pixels 20, and the size of the first edge line 51 in the second direction Y is set to be larger than the size of the second edge line 52 in the second direction Y, which may effectively disconnect at least one film layer in the light-emitting functional layer 202, may reduce probability of crosstalk between two adjacent sub-pixels and brightness degradation of sub-pixels, and is favorable for reducing a risk of color mixing on the display substrate when adjacent sub-pixels emit light of different colors; in addition, the material of the isolation structure 50 is different from the material of the defining portion 302, which may reduce mutual impact between the isolation structure 50 and the defining portion 302 during the fabrication process, and is favorable for the fabrication process; moreover, because the isolation structure 50 is provided between adjacent sub-pixels 20, it is also convenient to adjust the size of the isolation structure 50 in a timely manner according to different design requirements; for example, when it is necessary to change the size of the isolation structure 50 (e.g., increase a height of the isolation structure 50 in the first direction X), the size of the isolation structure 50 may be adjusted alone, which is easy to operate and has little impact on other structures in the display substrate.

For example, as shown in FIG. 18, the cross section of the isolation structure 50 that is sectioned by the above-described plane includes a side edge located between the position with the maximum cross-sectional size and the base substrate 10, an included angle u between at least a portion of the side edge and the second direction Y is 95° to 105°, and the maximum size of the isolation structure 50 in the first direction X is 0.7 μm to 1 μm. The cross section of the defining portion 302 that is sectioned by the above-described plane includes a third edge line 53 away from the base substrate 10, an included angle between a tangent line of at least a portion of the third edge line 53 and the second direction Y is 35° to 45°, and the maximum size of the defining portion 302 in the first direction X is 1.15 μm to 1.25 μm.

For example, as shown in FIG. 18, the cross section of the isolation structure 50 that is sectioned by the above-described plane has a shape of “trapezoid”, the cross section of the defining portion 302 that is sectioned by the above-described plane has a shape of “semi-circle”, and the maximum size of the isolation structure 50 in the first direction X is smaller than the maximum size of the defining portion 302 in the first direction X. For example, the maximum size of the isolation structure 50 in the first direction X may be at least one of 0.7 μm to 0.9 μm, 0.8 μm to 0.9 μm, 0.75 μm to 0.85 μm, and 0.80 μm to 0.95 μm, but it is not limited thereto. For example, the maximum size of the defining portion 302 in the first direction X may be at least one of 1.15 μm to 1.20 μm, 1.17 μm to 1.19 μm, 1.18 μm to 1.24 μm, and 1.19 μm to 1.23 μm, but it is not limited thereto. For example, an included angle u between at least a portion of the side edge of the cross section of the isolation structure 50 that is sectioned by the above-described plane and the second direction Y may be at least one of 95° to 100°, 96° to 102 °, 97° to 103°, and 98° to 104°, the side edge is located between the position with the maximum cross-sectional size and the base substrate 10, but it is not limited thereto. For example, an included angle between the tangent line of the third edge line 53 in the cross section of the defining portion 302 that is sectioned by the plane and the second direction Y may be at least one of 35° to 40°, 36° to 44°, 38° to 43°, and 37° to 42°, but it is not limited thereto.

For example, as shown in FIG. 18, the maximum size of the isolation structure 50 in the second direction Y may be 3 μm to 6 μm, for example, may be at least one of 3 μm to 5 μm, 4 μm to 6 μm, 4 μm to 5 μm, and 3 μm to 4 μm, but it is not limited thereto. For example, in the second direction, a distance between a certain isolation structure 50 and a light-emitting region adjacent to the certain isolation structure may be 4 μm to 7 μm, for example, may be at least one of 4 μm to 6 μm, 5 μm to 7 μm, 4.5 μm to 6.5 μm, 5.5 μm to 6 μm, and 5.5 μm to 7 μm, but it is not limited thereto. For example, in some embodiments, distances between the isolation structure 50 and two light-emitting regions adjacent to the isolation structure may be the same or different, which may be specifically set according to design requirements, and will not be limited in the embodiments of the present disclosure.

The maximum size of the isolation structure 50 in the first direction X and the maximum size of the defining portion 302 in the first direction X are set within the above-described appropriate range, and the above-described included angle u corresponding to the isolation structure 50 is matched with the included angle between the tangent line of the third edge line 53 corresponding to the defining portion 302 and the second direction Y, which may effectively isolate at least one layer of the light-emitting functional layer 202 and the second electrode 203, and is favorable for reducing a risk of crosstalk between adjacent sub-pixels.

For example, as shown in FIG. 18, an orthographic projection of the isolation structure 50 on the base substrate may not overlap with, or have a smaller overlapping area with, an orthographic projection of the defining portion 302 adjacent thereto on the base substrate, which will not be limited in the embodiments of the present disclosure.

For example, as shown in FIG. 2, FIG. 8, FIG. 9 and FIG. 18, for example, in the second direction Y, the distance between two adjacent light-emitting regions may be 14 μm to 20 μm, for example, may be at least one of 14 μm to 19 μm, 15 μm to 17 μm, 16 μm to 18 μm, 17 μm to 19 μm, 16 μm to 17 μm, and 14 μm to 18 μm, but it is not limited thereto.

For example, as shown in FIG. 2, FIG. 8, FIG. 9 and FIG. 18, in some practical products, a boundary between the first sub-defining portion and the second sub-defining portion in the first defining portion 303 may not be very clear, so that the first defining portion 303 may be an integral structure visually, but it is not limited thereto.

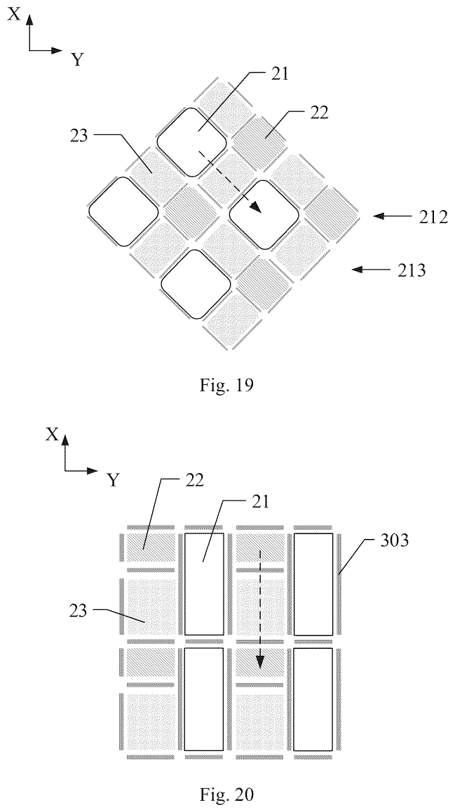

FIG. 19 is a partial schematic plan view of a display substrate corresponding to FIG. 18 provided by at least one embodiment of the present disclosure; and FIG. 20 is a partial schematic plan view of still another display substrate corresponding to FIG. 18 provided by at least one embodiment of the present disclosure. For example, FIG. 18 corresponds to the cross-sectional schematic diagrams respectively sectioned by dashed lines in FIG. 19 and FIG. 20.

For example, an arrangement mode of the plurality of sub-pixels in the display substrate shown in FIG. 19 may be the same as the arrangement mode of the plurality of sub-pixels in the display substrate shown in FIG. 10. For example, the display substrate shown in FIG. 19 differs from the display substrate shown in FIG. 10 in the structural form of the defining portion closely adjacent to the light-emitting region of the sub-pixel. For example, an arrangement mode of the plurality of sub-pixels in the display substrate shown in FIG. 20 may be the same as the arrangement mode of the plurality of sub-pixels in the display substrate shown in FIG. 11. For example, the display substrate shown in FIG. 20 differs from the display substrate shown in FIG. 11 in the structural form of the defining portion closely adjacent to the light-emitting region of the sub-pixel.

For example, as shown in FIG. 19 and FIG. 20, a light-emitting region of each sub-pixel 20 is surrounded by four isolation structures 50. One isolation structure 50 is provided between defining portions adjacent to opposite edges of two adjacent sub-pixels. For example, an extension direction of the isolation structure 50 is the same as an extension direction of at least part of the defining portion 302 adjacent thereto, but it is not limited thereto. For example, orthographic projections of the four isolation structures 50 surrounding the light-emitting region of the sub-pixel 20 have a shape of a non-closed ring, and second electrodes of adjacent sub-pixels 20 are connected at an opening of the non-closed ring, to ensure continuity of the second electrodes of the adjacent sub-pixel 20.

At least one embodiment of the present disclosure further provides a display apparatus, including any of the above-described display substrates.

FIG. 21 is a schematic diagram of a display apparatus provided by an embodiment of the present disclosure. As shown in FIG. 21, the display apparatus 500 includes a display substrate 100. The display substrate 100 is any of the above-described display substrates. Therefore, the technical effects of the above-described display substrate may also be reflected on the display apparatus, and no details will be repeated here.

The display substrate mentioned in the embodiment of the present disclosure may also be referred to as a display panel. For example, the display substrate may be a flexible display substrate, but it is not limited thereto. For example, the display apparatus 500 may be a display device such as an organic light-emitting diode display apparatus, as well as a television, a digital camera, a mobile phone, a watch, a tablet personal computer, a laptop, a navigator, and any other product or component having a display function including the display apparatus, and the embodiment of the present disclosure includes but is not limited thereto.

FIG. 22 is a spectral schematic diagram of a display substrate provided by an embodiment of the present disclosure.

For example, as shown in FIG. 22, in a low grayscale driving state corresponding to the green sub-pixel, when the display substrate shown in FIG. 1 is adopted, more obvious red light spectral energy appears in spectral distribution, indicating that crosstalk occurs between the green sub-pixel and the red sub-pixel, and the green sub-pixel leaks electricity to the red sub-pixel adjacent to the green sub-pixel and causes the red sub-pixel to emit light. By using the display substrate shown in FIG. 2 provided by the embodiment of the present disclosure, under the low grayscale driving state corresponding to the green sub-pixel, the spectral distribution trend shows an overall trend of gradual decrease, and the red spectral energy is significantly reduced. Therefore, the risks of the green sub-pixel leaking electricity to the red sub-pixel adjacent to the green sub-pixel and driving the red sub-pixel to emit light is effectively reduced, which improves display performance of the display substrate during low grayscale driving.

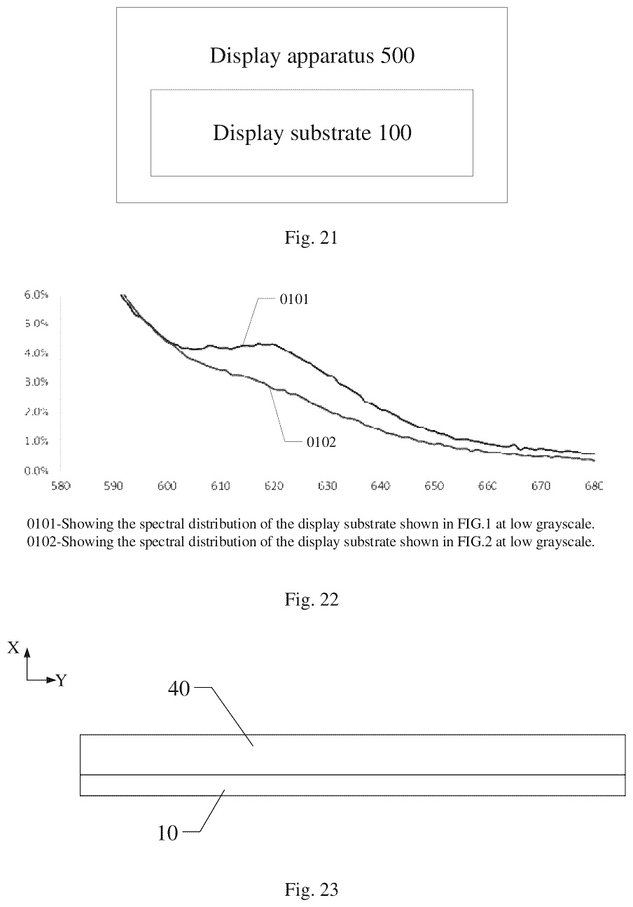

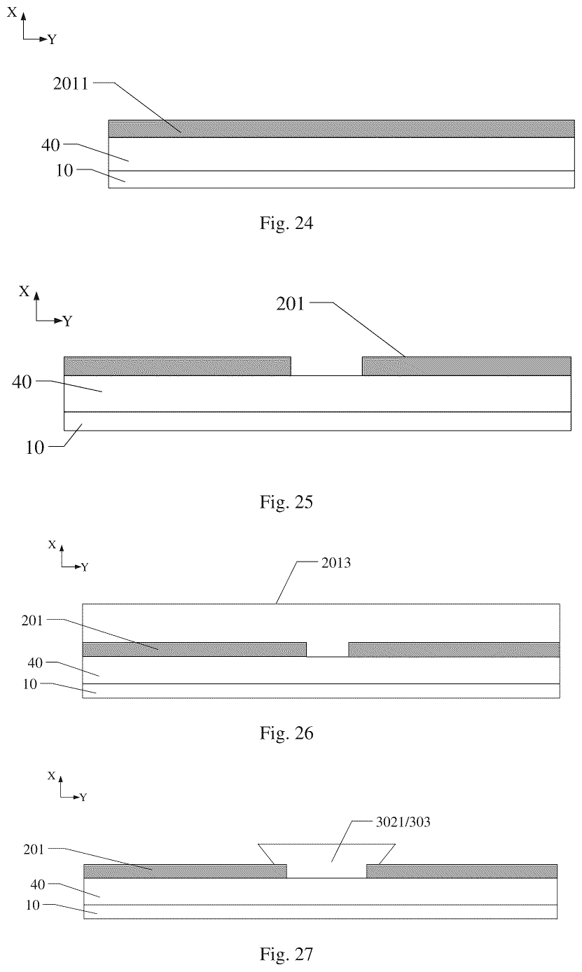

FIG. 23 to FIG. 40 are flow charts of a fabrication process of a display substrate provided by at least one embodiment of the present disclosure.

As shown in FIG. 23, a fabrication method of the display substrate provided by at least one embodiment of the present disclosure includes: forming a plurality of sub-pixels on the base substrate 10, which includes sequentially forming a first electrode, a light-emitting functional layer, and a second electrode of a light-emitting element in a first direction X, and forming a defining portion.

As shown in FIG. 23 to FIG. 25, a first conductive thin film 2011 is deposited on the base substrate 10, and the first conductive thin film 2011 is pattern, to form first electrodes 201.

Then, a pixel defining pattern is formed; the pixel defining pattern includes a plurality of openings and a defining portion surrounding the plurality of openings, at least a portion of the light-emitting element is located in the openings; and the defining portion includes a first defining portion located between adjacent light-emitting elements, in which the forming the first defining portion includes the following steps.

After forming the first electrodes 201 and before forming the light-emitting functional layer, as shown in FIG. 26 to FIG. 27, forming the defining portion includes: forming a first defining layer 2013 on the first electrodes 201, and patterning the first defining layer 2013, to form a first sub-defining portion 3021.

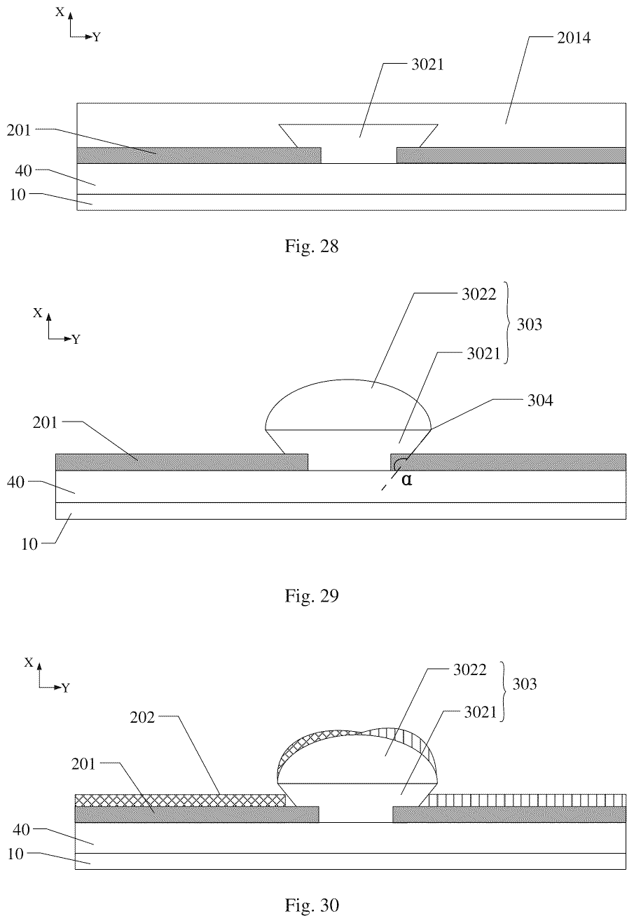

Then, as shown in FIG. 28 to FIG. 29, a second defining layer 2014 is formed on a side of the first sub-defining portion 3021 that is away from the base substrate 10, and the second defining layer 2014 is patterned to form a second sub-defining portion 3022. A size, in a second direction Y, of a cross section of the first defining portion 303 including the first sub-defining portion and the second sub-defining portion as described above that is sectioned by a plane is a cross-sectional size, along the first direction X, the cross-sectional size firstly increases and then decreases, and a position with the maximum cross-sectional size is located at an isolation portion 304 of the first defining portion 303. The above-described plane and the second direction Y are both perpendicular to an extension direction of the first defining portion 303, and the second direction Y is perpendicular to the first direction X.

As shown in FIG. 28 to FIG. 29, a material of the first defining layer 2013 is different from a material of the second defining layer 2014; for example, the material of the first defining layer 2013 has a first photosensitive characteristic such that the first defining layer 2013 is polymerized under illumination, and the material of the second defining layer 2014 has a second photosensitive characteristic such that the second defining layer 2014 is decomposed under illumination. The first defining layer 2013 and the second defining layer 2014 have different photosensitive characteristics, which facilitates formation and reduces a risk of damage to the first defining layer 2013 by the second defining layer 2014 during, for example, an exposure process.

For example, as shown in FIG. 28 to FIG. 29, a material of the first sub-defining portion 3021 may include phenolic resin and propylene glycol monomethyl ether acetate; for example, a material of the second sub-defining portion 3022 may include polyimide resin and propylene glycol monomethyl ether acetate, but it is not limited thereto.

As shown in FIG. 30, the fabrication method of the display substrate further includes: forming the light-emitting functional layer 202 on a side of the first defining portion 303 that is away from the base substrate 10, and isolating at least one layer of the light-emitting functional layer 202 at an edge of the isolation portion 304 that faces the light-emitting element.

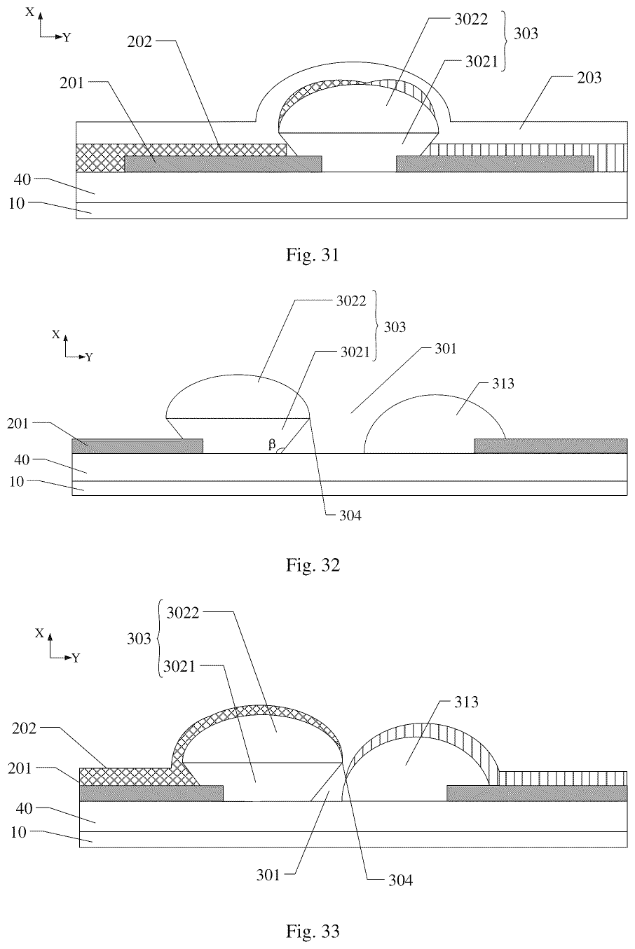

As shown in FIG. 31, the fabrication method of the display substrate further includes; disposing the second electrode 203 on a side of the light-emitting functional layer 202 that is away from the base substrate 10. For example, in the display substrate shown in FIG. 31, the second electrodes 203 are continuously arranged at the edge of the isolation portion 304 that faces the light-emitting element, to ensure continuity of second electrodes of adjacent sub-pixels.

For example, as shown in FIG. 29 to FIG. 31, the cross section of the first defining portion 303 includes a side edge located between the position with the maximum cross-sectional size and the base substrate 10, an included angle a between at least a portion of the side edge and the second direction Y is 95° to 105°, and a maximum size of the first sub-defining portion 3021 in the first direction X is 0.7 μm to 1 μm. The cross section of the first defining portion 303 includes an edge line located on a side of the position with the maximum cross-sectional size that is away from the base substrate 10, an included angle between a tangent line at a point connecting the edge line and the position with the maximum cross-sectional size and the second direction Y is 35° to 45°, and the maximum size of the second sub-defining portion 3022 in the first direction X is 1.15 μm to 1.25 μm, but it is not limited thereto.

For example, in some embodiments of the present disclosure, as shown in FIG. 26 and FIG. 27, the patterning the first defining layer 2013 to form the first defining portion 303, may include: making an orthographic projection of the first defining portion 303 surrounding the opening on the base substrate 10 present a shape of non-closed ring, and providing at least one first defining portion 303 between light-emitting regions of two adjacent sub-pixels of different colors, so that second electrodes 203 of adjacent light-emitting elements may be at least partially connected at a notch of the non-closed ring.

For example, as shown in FIG. 28 and FIG. 32, while patterning the second defining layer 2014 to form the second sub-defining portion 3022, the method may further include: patterning the second defining layer 2014 to form the second defining portion 313, and making the edge of the light-emitting region of the sub-pixel 20 that is located at the notch of the non-closed ring be closely adjacent to the second defining portion 313. For example, as shown in FIG. 33, the light-emitting functional layer 202 is formed on a side of the second sub-defining portion 3022 that is away from the base substrate 10, and at least one layer of the light-emitting functional layer 202 is isolated at the edge of the isolation portion 304 that faces the light-emitting element. For example, at least one layer of the light-emitting functional layer 202 is isolated between the first defining portion 303 and the second defining portion 313 closely adjacent thereto.

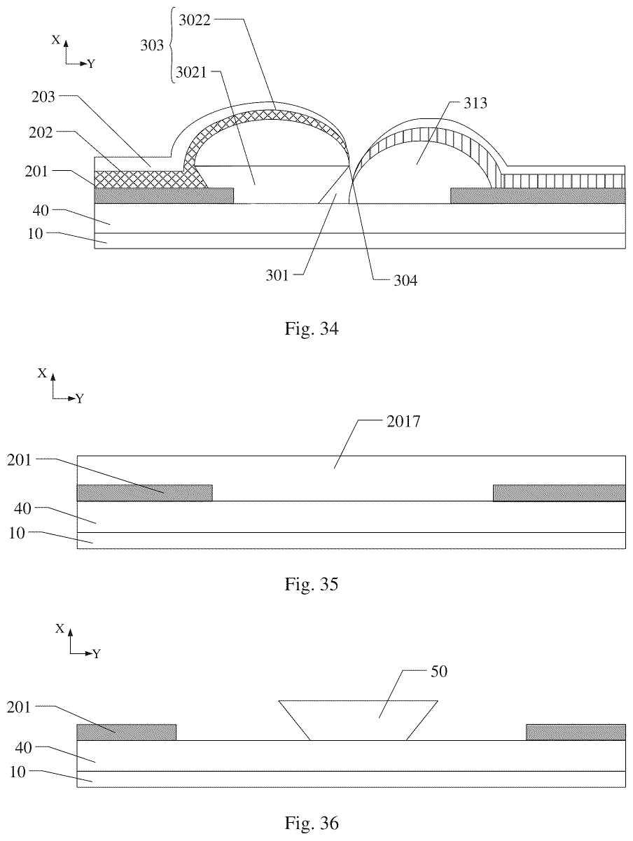

For example, as shown in FIG. 34, the second electrode 203 is formed on a side of the light-emitting functional layer 202 that is away from the base substrate 10, and at least one layer of the second electrode 203 is isolated between the first defining portion 303 and the second defining portion 313 closely adjacent thereto.

For example, as shown in FIG. 32 to FIG. 34, the cross section of the first defining portion 303 that is sectioned by the above-described plane includes a side edge located between the position with the maximum cross-sectional size and the base substrate 10, an included angle β between at least a portion of the side edge and the second direction Y is 100° to 110°, and a maximum size of the first sub-defining portion 3021 in the first direction X is 1 μm to 1.2 μm. For example, the cross section of the first defining portion 303 that is sectioned by the above-described plane includes an edge line located on a side of the position with the maximum cross-sectional size that is away from the base substrate 10, an included angle between a tangent line at a point connecting the edge line and the position with the maximum cross-sectional size and the second direction Y is 35° to 45°, and the maximum size of the second sub-defining portion 3022 in the first direction X is 0.9 μm to 1.1 μm, but it is not limited thereto. For example, as shown in FIG. 33 to FIG. 34, when at least one film layer of the light-emitting functional layer 202 and the second electrode 203 are isolated by the isolation portion 304 of the first defining portion 303, a portion of the at least one film layer of the light-emitting functional layer 202 or a portion of the second electrode 203 may also be located between the first defining portion 303 and the second defining portion 313, for example, may fall on a side surface of the structural layer 40 that is away from the base substrate 10, but it is not limited thereto.

For example, an embodiment of the present disclosure further provides another fabrication method of a display substrate, including: forming a plurality of sub-pixels on a base substrate; forming a sub-pixel, including sequentially forming a first electrode, a light-emitting functional layer, and a second electrode of a light-emitting element in a first direction X.

As shown in FIG. 23 to FIG. 25, a first conductive thin film 2011 is deposited on a base substrate 10, and the first conductive thin film 2011 is pattern, to form first electrodes 201.

After forming the first electrode 201 and before forming the light-emitting functional layer, as shown in FIG. 35 to FIG. 36, the fabrication method of the display substrate includes: forming a first material layer 2017 on the first electrode 201 and patterning the first material layer 2017 to form an isolation structure 50.

Further, the fabrication method of the display substrate includes forming a pixel defining pattern, the pixel defining pattern including a plurality of openings and defining portions surrounding the plurality of openings, and at least a portion of the light-emitting element being located in the opening, in which the forming a defining portion includes the following steps.

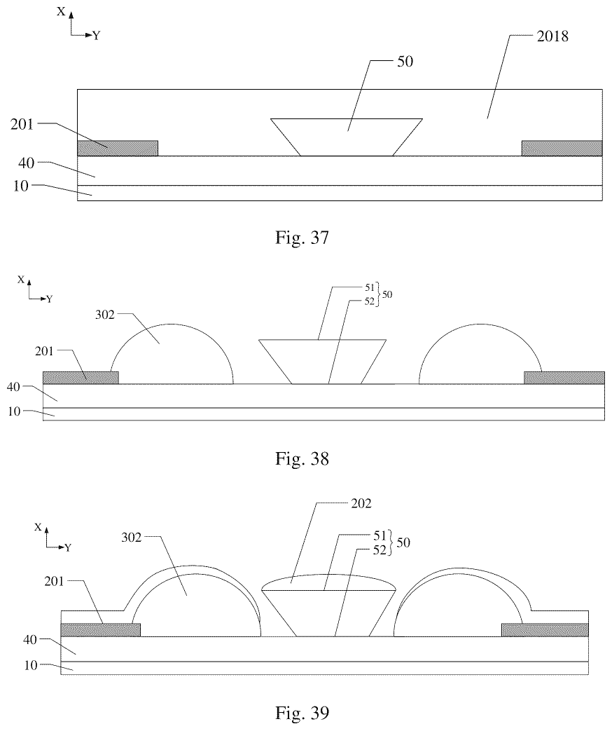

As shown in FIG. 37 to FIG. 38, a second material layer 2018 is formed on a side of the isolation structure 50 that is away from the base substrate 10, and the second material layer 2018 is patterned to form defining portions 302. The isolation structure 50 is located between defining portions 302 respectively closely adjacent to two adjacent openings, and a material of the isolation structure 50 is different from a material of the defining portions 302.

As shown in FIG. 37 to FIG. 38, in a second direction Y, a size of a first edge line 51 of the cross section of the isolation structure 50 that is sectioned by a plane is larger than a size of a second edge line 52 of the cross section, the first edge line is an edge line of the cross section away from the base substrate 10, and the second edge line 52 is an edge line of the cross section close to the base substrate; both the plane and the second direction Y are perpendicular to an extension direction of the first defining portion 303, and the second direction Y is perpendicular to the first direction X.

For example, as shown in FIG. 39, the light-emitting functional layer 202 is formed on a side of the defining portion 302 that is away from the base substrate 10, and at least one layer of the light-emitting functional layer 202 is isolated at the edge of the isolation portion 304 that faces the light-emitting element.

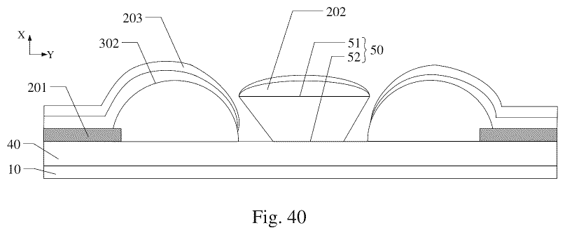

For example, as shown in FIG. 40, the second electrodes 203 are formed on a side of the light-emitting functional layer 202 that is away from the base substrate 10, so that the second electrodes 203 are isolated at the edge of the isolation structure 50 that faces the light-emitting element, and portions of second electrodes 203 of adjacent light-emitting elements are continuously arranged.

For example, as shown in FIG. 38 to FIG. 40, the cross section of the isolation structure 50 that is sectioned by the above-described plane includes a side edge located between the position with the maximum cross-sectional size and the base substrate 10, an included angle u between at least a portion of the side edge and the second direction Y is 95° to 105°, and the maximum size of the isolation structure 50 in the first direction X is 0.7 μm to 1 μm. The cross section of the defining portion 302 that is sectioned by the plane includes a third edge line 53 away from the base substrate 10, an included angle between a tangent line of at least a portion of the third edge line 53 and the second direction Y is 35° to 45°, and the maximum size of the defining portion 302 in the first direction X is 1.15 μm to 1.25 μm, but it is not limited thereto.

For example, in some embodiments of the present disclosure, as shown in FIG. 31, FIG. 34 and FIG. 40, the base substrate 10 may be a flexible base substrate. For example, a step of forming a base substrate 10 may include sequentially forming a first flexible material layer, a first inorganic material layer, a semiconductor layer, a second flexible material layer, and a second inorganic material layer stacked on a glass carrier plate. The first flexible material layer and the second flexible material layer are made of polyimide (PI), polyethylene terephthalate (PET), or surface-treated polymer soft films. For example, the first inorganic material layer and the second inorganic material layer are made of silicon nitride (SiNx) or silicon oxide (SiOx), etc., to improve water and oxygen resistance of the base substrate; and the first material layer and the second inorganic material layer are also referred to as barrier layers. The semiconductor layer is made of amorphous silicon (a-si), but it is not limited thereto.

For example, in some embodiments of the present disclosure, as shown in FIG. 31, FIG. 34 and FIG. 40, before forming the first electrodes 201, the fabrication method of the display substrate may further include forming a structural layer 40 located on the base substrate 10. For example, steps of forming the structural layer 40 may include forming a planarization layer, a layer where an active semiconductor pattern is located, a film layer where a gate line is located, a film layer where a data line is located, a plurality of insulation layers, etc.; and specific forms and arrangement modes of the respective film layers may be set according to design requirements, which will not be limited in the embodiments of the present disclosure.

For example, in some embodiments of the present disclosure, as shown in FIG. 31, FIG. 34 and FIG. 40, the fabrication method of the display substrate further includes forming an encapsulation layer, for example, may include: sequentially forming a first encapsulation layer, a second encapsulation layer, and a third encapsulation layer on a side of the second electrode 203 that is away from the base substrate 10, so that the display substrate has a good encapsulation effect, and prevent invasion of water vapor or impurities.

The following statements should be noted:
(1) The accompanying drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto. The protection scope of the present disclosure should be based on the protection scope of the claims.

1. A display substrate, comprising:
a base substrate;
a plurality of sub-pixels, located on the base substrate, each sub-pixel among at least some sub-pixels comprising a light-emitting element, the light-emitting element comprising a light-emitting functional layer having a plurality of film layers, the plurality of film layers being stacked in a first direction;
a pixel defining pattern, comprising a plurality of openings and a defining portion surrounding the plurality of openings, at least a portion of the light-emitting element being located in the opening;
wherein the defining portion comprises a first defining portion located between adjacent light-emitting elements, a size, in a second direction, of a cross section of the first defining portion as sectioned by a plane is a cross-sectional size; in the first direction, the cross-sectional size firstly increases and then decreases, a position with a maximum cross-sectional size is located at an isolation portion of the first defining portion; both the plane and the second direction are perpendicular to an extension direction of the first defining portion, the first direction is perpendicular to the base substrate, and the second direction is perpendicular to the first direction;
at least a portion of a pattern of at least one layer in the light-emitting functional layer is located on a side of the first defining portion that is away from the base substrate, and an orthographic projection of an edge of the at least portion of the pattern falls into an orthographic projection of the first defining portion on the base substrate.

2. The display substrate according to claim 1, wherein the light-emitting element further comprises a first electrode and a second electrode located on both sides of the light-emitting functional layer in the first direction, the first electrode is located between the light-emitting functional layer and the base substrate;
the first defining portion comprises a first sub-defining portion and a second sub-defining portion stacked, the first sub-defining portion is located between the second sub-defining portion and the base substrate, a material of the first sub-defining portion is different from a material of the second sub-defining portion, and the isolation portion comprises a border between the first sub-defining portion and the second sub-defining portion.

3. The display substrate according to claim 2, wherein an interface between the first sub-defining portion and the second sub-defining portion in contact with each other is the position with the maximum cross-sectional size.

4. The display substrate according to claim wherein a surface of the first sub-defining portion that is in contact with the second sub-defining portion is a first surface, a surface of the second sub-defining portion that is in contact with the first sub-defining portion is a second surface, and an orthographic projection of the second surface on the base substrate is completely located within an orthographic projection of the first surface on the base substrate.

5. The display substrate according to claim 2, wherein a surface of the second sub-defining portion away from the base substrate comprises a curved surface bent towards a side away from the base substrate or a flat surface parallel to the base substrate,

6. (canceled)

7. The display substrate according to claim 2, wherein the at least the portion of the pattern of the at least one layer in the light-emitting functional layer comprises a first portion and a second portion, an orthographic projection of an edge of the first portion on the base substrate falls into an orthographic projection of the first defining portion on the base substrate, the edge of the first portion is located on a side of the isolation portion away from the base substrate, and an edge of the second portion is located on a side of the isolation portion close to the base substrate.

8. (canceled)

9. The display substrate according to claim 2, wherein second electrodes of at least some of adjacent sub-pixels are continuously arranged at an edge of the isolation portion.

10. The display substrate according to claim 9, wherein the cross section comprises a side edge located between the position with the maximum cross-sectional size and the base substrate, an included angle between at least a portion of the side edge and the second direction is 95° to 105°, and a maximum size of the first sub-defining portion in the first direction is 0.7 μm to 1 μm;
the cross section comprises an edge line located on a side of the position with the maximum cross-sectional size away from the base substrate, an included angle between a tangent line at a point connecting the edge line and the position with the maximum cross-sectional size and the second direction is 35° to 45°, and a maximum size of the second sub-defining portion in the first direction is 1.15 μm to 1.25 μm.

11. (canceled)

12. The display substrate according to claim 9, wherein two adjacent sub-pixels arranged along the second direction are configured to emit light of different colors, and one first defining portion is provided between the two adjacent sub-pixels.

13. The display substrate according to claim 2, wherein second electrodes of adjacent sub-pixels are isolated at an edge of the isolation portion.

14. The display substrate according to claim 13, wherein the cross section comprises a side edge located between the position with the maximum cross-sectional size and the base substrate, an included angle between at least a portion of the side edge and the second direction is 100° to 110°, and a maximum size of the first sub-defining portion in the first direction is 1 μm to 1.2 μm;
the cross section comprises an edge line located on a side of the position with the maximum cross-sectional size away from the base substrate, an included angle between a tangent line at a point connecting the edge line and the position with the maximum cross-sectional size and the second direction is 35° to 45°, and a maximum size of the second sub-defining portion in the first direction is 0.9 μm to 1.1 μm.

15. (canceled)

16. The display substrate according to claim 13, wherein the defining portion further comprises a second defining portion, the second defining portion is closely adjacent to an edge of the light-emitting region of the light-emitting element, and an extension direction of the second defining portion is the same as the extension direction of the first defining portion;
in the first direction, a size of the second defining portion is smaller than a size of the first defining portion, and a material of the second defining portion is the same as that of the second sub-defining portion.

17. The display substrate according to claim 16, wherein, in the first direction, the size of the second defining portion is larger than a size of the second sub-defining portion.

18. The display substrate according to claim 16, wherein two adjacent sub-pixels arranged along the second direction are configured to emit light of different colors, two first defining portions are provided at an interval between the two adjacent sub-pixels, or, one first defining portion and one second defining portion are provided at an interval between the two adjacent sub-pixels.

19. The display substrate according to claim 1, wherein the position with the maximum cross-sectional size is further away from the base substrate than a surface of the light-emitting functional layer away from the base substrate.

20. The display substrate according to claim 2, wherein
the material of the first sub-defining portion has a first photosensitive characteristic such that the first sub-defining portion is polymerized under illumination; and
the material of the second sub-defining portion has a second photosensitive characteristic such that the second sub-defining portion is decomposed under illumination.

21-30. (canceled)

31. A display substrate, comprising:
a base substrate;
a plurality of sub-pixels, located on the base substrate, each sub-pixel among at least some sub-pixels comprising a light-emitting element, the light-emitting element comprising a light-emitting functional layer as well as a first electrode and a second electrode located on both sides of the light-emitting functional layer along a first direction, the first electrode being located between the light-emitting functional layer and the base substrate, and the first direction being perpendicular to the base substrate;
a pixel defining pattern, comprising a plurality of openings and defining portions surrounding the plurality of openings, and at least a portion of the light-emitting clement being located within the opening;
an isolation structure, located between defining portions respectively adjacent to two adjacent openings, and a material of the isolation structure being different from a material of the defining portion,
wherein, in a second direction, a maximum size of a first edge line away from the base substrate of a cross section of the isolation structure, as sectioned by a plane, is larger than a maximum size of a second edge line close to the base substrate of the cross section, the plane and the second direction are both perpendicular to an extension direction of the defining portion, and the second direction is perpendicular to the first direction;
between at least two adjacent light-emitting elements, at least one layer of the light-emitting functional layer is isolated at an edge of the isolation structure, and at least a portion of a second electrode corresponding to at least one certain light-emitting element extends from a light-emitting region of the certain light-emitting element to a light-emitting region of at least one of light-emitting elements adjacent to the certain light-emitting element.

32. The display substrate according to claim 31, wherein a material of the isolation structure comprises phenolic resin and propylene glycol monomethyl ether acetate, and/or a material of the defining portion comprises polyimide resin and propylene glycol monomethyl ether acetate.

33. The display substrate according to claim 31, wherein the cross section comprises a side edge located between the position with the maximum cross-sectional size and the base substrate, an included angle between at least a portion of the side edge and the second direction is 95° to 105°, and a maximum size of the isolation structure in the first direction is 0.7 μm to 1 μm;
a cross section of the defining portion that is sectioned by the plane comprises a third edge line away from the base substrate, an included angle between a tangent line of at least a portion of the third edge line and the second direction is 35° to 45°, and a maximum size of the defining portion in the first direction is 1.15 μm to 1.25 μm.

34. (canceled)

35. (canceled)

36. A display apparatus, comprising the display substrate according to claim 1.
